(19) United States
(12) Patent Application Publication
(10) Pub. No.: US 2017/0229562 A1
(43) Pub. Date: Aug. 10, 2017

(54) SEMICONDUCTOR DEVICE MANUFACTURING METHOD

(71) Applicant: Renesas Electronics Corporation, Tokyo (JP)

(72) Inventor: Shigeki KATOU, Tokyo (JP)

(73) Assignee: Renesas Electronics Corporation, Tokyo (JP)

(21) Appl. No.: 15/409,966

(22) Filed: Jan. 19, 2017

(30) Foreign Application Priority Data
Feb. 4, 2016 (JP) 2016-019890

(51) Int. Cl. H01L 29/66; H01L 21/02; H01L 21/768; H01L 21/304; H01L 27/1157; H01L 29/792

(52) U.S. Cl. CPC H01L 29/66833; H01L 29/66545; H01L 27/1157; H01L 29/792; H01L 21/76895; H01L 21/304; H01L 21/02068

(57) ABSTRACT

When forming a MISFET by replacing a dummy gate electrode with a metal gate electrode in a gate last process, formation caused by polishing of an interlayer insulation film of a silicide layer over an upper surface of the dummy gate electrode to result in hampering the removal of the dummy gate is prevented. In the gate last process, when an interlayer insulation film is polished to expose an upper surface of a dummy gate electrode, a slurry mixed with an acidic aqueous solution is used to prevent silicide layer formation over the upper surface of the dummy gate electrode.

### CROSS-REFERENCE TO RELATED APPLICATIONS

The disclosure of Japanese Patent Application No. 2016-019890 filed on Feb. 4, 2016 including the specification, drawings and abstract is incorporated herein by reference in its entirety.

### BACKGROUND

The present invention relates to a method for manufacturing a semiconductor device and is applicable to, for example, manufacture of a semiconductor device including a silicide layer.

Transistors including a metal gate electrode and a high dielectric-constant film (a high-k film) are known as transistors which can be miniaturized for formation in logic units of next-generation microcomputers. As a method of forming such transistors, a so-called gate last process is known in which, after a dummy gate electrode is formed on a substrate, the dummy gate electrode is replaced with a metal gate electrode.

Also, as an electrically writable/erasable non-volatile semiconductor memory device, a memory cell is widely used which includes a conductive floating gate electrode surrounded by an oxide film or a trapping insulation film formed under the gate electrode of a MISFET. A split gate type MONOS (Metal Oxide Nitride Oxide Semiconductor) cell is a non-volatile semiconductor memory device using a trapping insulation film.

In Japanese Unexamined Patent Application Publication No. 2014-154790, a technique is disclosed in which, when a memory cell and a MISFET of a logic unit are to be formed on a same chip, first a silicide layer is formed over the source and drain regions of a MISFET, next a metal gate electrode of the MISFET is formed by a gate last process, then a silicide layer is formed over the gate electrodes of the memory cell.

### SUMMARY

In the gate last process, after a silicide layer is formed over upper surfaces of the source and drain regions and gate electrodes of various types of MISFETs (Metal Insulator Semiconductor Field Effect Transistors), the respective elements are covered with an interlayer insulation film, then the upper surface of the interlayer insulation film is polished to expose the upper surfaces of the gate electrodes. In the polishing process, the silicide layer formed over the gate electrodes is removed and, at this time, the heat generated by polishing causes silicide layer particles separated from the gate electrodes to react with silicon contained in the gate electrodes. As a result, a silicide layer is again formed over the gate electrodes.

In the gate last process, among the gate electrodes, pseudo-gate electrodes (dummy gate electrodes) are required to be replaced by metal gate electrodes after the polishing process, but the silicide layer formed as a result of the polishing process makes it difficult to remove the dummy gate electrodes.

Other objects and novel features of the present invention will become apparent from the description of this specification and the attached drawings.

Of the embodiments being disclosed in this application, typical ones are outlined below.

According to one embodiment of the present invention, when forming a MONOS memory and a MISFET to be formed in a gate last process on a same chip, after a silicide layer to cover an upper surface of a dummy gate electrode is formed, the dummy gate electrode is covered with an interlayer insulation film, then the upper surface of the dummy gate electrode is exposed from the interlayer insulation film by polishing the interlayer insulation film using an acidic slurry.

According to one embodiment of the present invention, the reliability of a semiconductor device can be improved. Particularly, the dummy gate electrode can be appropriately removed without being hampered by the silicide layer formed as a result of polishing.

According to one embodiment of the present invention, the cost of manufacturing semiconductor devices can be reduced. Particularly, the process for removing a silicide layer formed over dummy gate electrodes can be omitted.

### BRIEF DESCRIPTION OF THE DRAWINGS

FIG. 1 is a sectional view of a semiconductor device in a manufacturing step according to a first embodiment of the present invention.

FIG. 2 is a sectional view of the semiconductor device in a manufacturing step subsequent to the step shown in FIG. 1.

FIG. 3 is a sectional view of the semiconductor device in a manufacturing step subsequent to the step shown in FIG. 2.

FIG. 4 is a sectional view of the semiconductor device in a manufacturing step subsequent to the step shown in FIG. 3.

FIG. 5 is a sectional view of the semiconductor device in a manufacturing step subsequent to the step shown in FIG. 4.

FIG. 6 is a sectional view of the semiconductor device in a manufacturing step subsequent to the step shown in FIG. 5.

FIG. 7 is a sectional view of the semiconductor device in a manufacturing step subsequent to the step shown in FIG. 6.

FIG. 8 is a sectional view of the semiconductor device in a manufacturing step subsequent to the step shown in FIG. 7.

FIG. 9 is a sectional view of the semiconductor device in a manufacturing step subsequent to the step shown in FIG. 8.

FIG. 10 is a sectional view of the semiconductor device in a manufacturing step subsequent to the step shown in FIG. 9.

FIG. 11 is a sectional view of the semiconductor device in a manufacturing step subsequent to the step shown in FIG. 10.

FIG. 12 is a sectional view of the semiconductor device in a manufacturing step subsequent to the step shown in FIG. 11.

FIG. 13 is a sectional view of the semiconductor device in a manufacturing step subsequent to the step shown in FIG. 12.

FIG. 14 is a sectional view of the semiconductor device in a manufacturing step subsequent to the step shown in FIG. 13.

FIG. 15 is a sectional view of the semiconductor device in a manufacturing step subsequent to the step shown in FIG. 14.

FIG. 16 is an overhead view of a polishing apparatus used in a semiconductor device manufacturing process according to the present embodiment.

FIG. 17 is a sectional view of the semiconductor device in a manufacturing step subsequent to the step shown in FIG. 15.

FIG. 18 is a sectional view of the semiconductor device in a manufacturing step subsequent to the step shown in FIG. 17.

FIG. 19 is a sectional view of the semiconductor device in a manufacturing step subsequent to the step shown in FIG. 18.

FIG. 20 is a sectional view of the semiconductor device in a manufacturing step subsequent to the step shown in FIG. 19.

FIG. 21 is a sectional view of the semiconductor device in a manufacturing step subsequent to the step shown in FIG. 20.

FIG. 22 is a sectional view of the semiconductor device in a manufacturing step subsequent to the step shown in FIG. 21.

FIG. 23 is a sectional view of the semiconductor device in a manufacturing step subsequent to the step shown in FIG. 22.

FIG. 24 is a sectional view of the semiconductor device in a manufacturing step subsequent to the step shown in FIG. 23.

FIG. 25 is a sectional view of the semiconductor device in a manufacturing step subsequent to the step shown in FIG. 24.

FIG. 26 is a sectional view of the semiconductor device in a manufacturing step subsequent to the step shown in FIG. 25.

FIG. 27 is a sectional view of the semiconductor device in a manufacturing step subsequent to the step shown in FIG. 26.

FIG. 28 is a table listing example voltages to be applied to different parts of a memory cell selected as a target of a “write,” “erase” or “read” operation.

FIG. 29 is a sectional view of a semiconductor device in a manufacturing step according to a second embodiment of the present invention.

FIG. 30 is a sectional view of the semiconductor device in a manufacturing step subsequent to the step shown in FIG. 29.

FIG. 31 is a sectional view of a semiconductor device in a manufacturing step according to a third embodiment of the present invention.

FIG. 32 is a sectional view of the semiconductor device in a manufacturing step subsequent to the step shown in FIG. 31.

FIG. 33 is a sectional view of the semiconductor device in a manufacturing step according to the comparison example.

### DETAILED DESCRIPTION

Embodiments of the present invention will be described below in detail with reference to drawings. Note that, in all drawings referred to in describing the following embodiments, members having identical functions are denoted by identical symbols and such members will not be repeatedly described. As a rule, in describing the following embodiments, identical or similar parts will not be repeatedly described except when particularly necessary.

The semiconductor device of the embodiments being described in this specification includes a non-volatile memory (e.g. a non-volatile memory element, a flash memory, or a non-volatile semiconductor memory device). The following embodiments will be described based on the assumption that the non-volatile memory includes a memory cell formed based on an n-channel type MISFET (Metal Insulator Semiconductor Field Effect Transistor).

Also, in the embodiments being described in this application, polarities (polarities of voltages applied for write, erase or read operation, or carrier polarities) are assumed for describing the operation of a memory cell formed based on an n-channel MISFET. In principle, by reversing all polarities including the polarities of applied potentials and carrier conductivity types, the same operation can be realized with a memory cell formed based on a p-channel MISFET. Also, in describing this application, a silicide layer which is formed by reaction between a metal film and a semiconductor film and a semiconductor film are differentiated. Namely, the silicide as referred to in this application is a compound between metal and silicon and is not a semiconductor.

### First Embodiment

<Semiconductor Device Manufacturing Method>

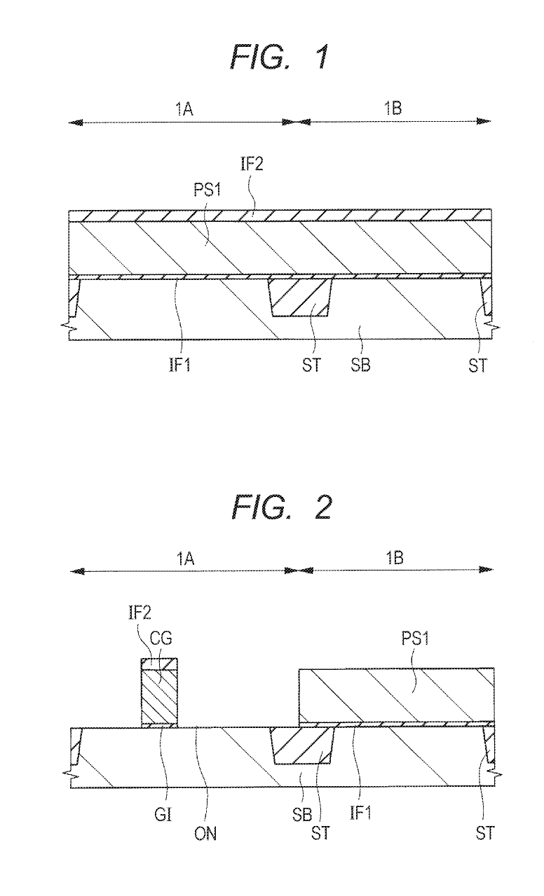

A semiconductor device manufacturing method according to the first embodiment will be described with reference to FIGS. 1 to 27.

FIGS. 1 to 15 and 17 to 27 are sectional views of a semiconductor device being manufactured according to the present embodiment. FIG. 16 is an overhead view of a polishing apparatus used in a semiconductor device manufacturing process according to the present embodiment. In each of FIGS. 1 to 15 and 17 to 27, a memory cell area 1A is shown on the left side and a peripheral circuit area 1B is shown on the right side. The memory cell area 1A is shown to illustrate formation of a memory cell included in a non-volatile memory. The peripheral circuit area 1B is shown to illustrate formation of a MISFET.

In the following, formation of a memory cell including an n-channel type MISFET (a control transistor and a memory transistor) in the memory cell area 1A will be described, but it is also possible to form a MISFET (a control transistor and a memory transistor) of an opposite conductivity type, i.e. a p-channel type MISFET, in the memory cell area 1A. Also, in the following, formation of an n-channel type MISFET in the peripheral circuit area 1B will be described, but it is also possible to form a p-channel type MISFET in the peripheral circuit area 1B.

It is also possible to form both of an n-channel type MISFET and a p-channel type MISFET, i.e. a CMISFET (complementary MISFET) in the peripheral circuit area 1B. Although, for the present embodiment, formation in the peripheral circuit area 1B of a MISFET with a relatively low withstand voltage will be described, a MISFET with a high withstand voltage which differs from the low withstand voltage MISFET in gate length or gate insulation film thickness is also formed in the peripheral circuit area 1B.

Referring to FIG. 1, in a semiconductor device manufacturing process, first, a semiconductor substrate (semiconductor wafer) SB is prepared. The semiconductor substrate SB contains p-type monocrystalline silicon (Si) having a specific resistance of about, for example, 1 to 10 Ωcm. Subsequently, plural element separation regions ST to define active regions are formed in the main surface of the semiconductor substrate SB.

The element separation regions ST are each formed of insulating material such as silicon oxide and can be formed, for example, by an STI (Shallow Trench Isolation) method or a LOCOS (Local Oxidation of Silicon) method. In this application, formation of element separation regions by an STI method will be described.

To form element separation regions, after a silicon oxide film and a silicon nitride film are formed in this order over the semiconductor substrate SB, the silicon nitride film and the silicon oxide film are etched by a photolithography technique and a dry etching method, then plural grooves are formed on the upper surface of the semiconductor substrate SB.

Subsequently, an insulation film made of, for example, silicon oxide is buried in the grooves and the insulation films formed over the semiconductor substrate SB are removed, for example, in a polishing process, causing element separation regions ST to be formed. Element separation regions ST are formed, for example, between the memory cell area 1A and the peripheral circuit area 1B and between MISFETs formed in the peripheral circuit area 1B.

Next, though not shown, p-wells are formed in the main surface of the semiconductor substrate SB in the memory cell area 1A and the peripheral circuit area 1B. P-wells can be formed, for example, by implanting p-type impurities, for example, boron (B) into the semiconductor substrate SB by an ion implantation method. It is possible to form p-wells in regions where memory cells and high or low withstand voltage MISFETs are formed in a same ion implantation process, but it is also possible to form p-wells in the respective regions in different ion implantation processes so as to optimize characteristics of the respective elements.

Subsequently, an insulation film IF1 for gate insulation is formed over the main surface of the semiconductor substrate SB. Namely, the insulation film IF1 is formed over the upper surface of the semiconductor substrate SB including the memory cell area 1A and the peripheral circuit area 1B. The insulation film IF1 may be, for example, a silicon oxide film. The insulation film IF1 may be formed in different processes for the memory cell area 1A and for the peripheral circuit area 1B, respectively, so as to make the film thickness different between the memory cell area 1A and the peripheral circuit area 1B.

Subsequently, a silicon film PS1 is formed over the semiconductor substrate SB so as to cover the upper surface of the insulation film IF1, for example, by a CVD (Chemical Vapor Deposition) method. The silicon film PS1 is a polycrystalline silicon film. It is possible to form the silicon film PS1 initially as an amorphous silicon film, then change the amorphous silicon film into a polycrystalline silicon film by heat treatment. Also, the silicon film PS1 can be made a low-resistance semiconductor film (doped polysilicon film) by introducing impurities during the film forming process or by implanting impurities by an ion implantation method after the film forming process. As the n-type impurities to be introduced into the silicon film PS1, phosphorus (P) can be suitably used.

Subsequently, an insulation film IF2 is formed over the silicon film PS1, for example, by a CVD method. The insulation film IF2 is a cap insulation film formed of, for example, silicon nitride (SiN). The insulation film IF2 can be made about, for example, 20 to 50 nm thick.

Next, as shown in FIG. 2, the film stack formed of the insulation film IF2, silicon film PS1 and insulation film IF1 in the memory cell area 1A is patterned by using a photolithography technique and an etching technique. This forms a gate insulating film GI formed of the insulation film IF1 in the memory cell area 1A. In the etching process, a control gate electrode CG made of the silicon film PS1 in the memory cell area 1A is formed. The control gate electrode CG is a pattern to be made a control gate electrode by being changed into silicide in a later process. The pattern extends, in a planar view, in the gate width direction, i.e. in the depth direction as seen in FIG. 2.

The above patterning process can be carried out, for example, as follows. The control gate electrode CG and the gate insulation film GI are formed by processing the insulation film IF2, silicon film PS1, and insulation film IF1 in the memory cell area 1A using a photolithography technique and a dry etching method. It is also possible to first process the insulation film IF2 in the memory cell area 1A using a photolithography technique and a dry etching method and then to process the silicon film PS1 and the insulation film IF1 using the insulation film IF2 as a mask.

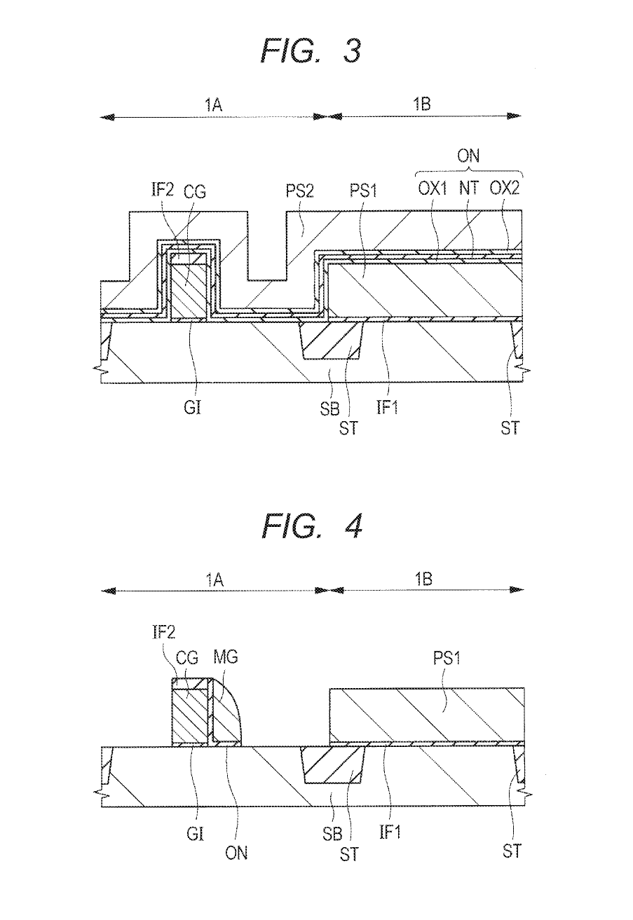

Subsequently, as shown in FIG. 3, the insulation film IF2 in the peripheral circuit area 1B is removed using a photolithography technique and a wet etching method. As a result, the upper surface of the silicon film PS1 in the peripheral circuit area 1B is exposed. In this process, the insulation film IF2 in the memory cell area 1A is not removed.

Next, all over the main surface of the semiconductor substrate SB, an ONO (oxide-nitride-oxide) film ON to be made a gate insulation film for a memory transistor is formed. The ONO film ON covers, in the memory cell area 1A, the upper surface of the semiconductor substrate SB and the side walls and upper surface of the film stack formed of the gate insulation film GI, insulation film IF2 and control gate electrode CG and covers, in the peripheral circuit area 1B, the side walls and upper surface of the film stack including the insulation film IF1 and silicon film PS1.

The ONO film ON is an insulation film having an internal charge accumulation part. To be specific, the ONO film ON is a film stack including a silicon oxide film OX1 formed over the semiconductor substrate SB, a silicon nitride film NT formed over the silicon oxide film OX1 and a silicon oxide film OX2 formed over the silicon nitride film NT.

The silicon oxide films OX1 and OX2 can be formed, for example, by oxidation treatment (thermal oxidation treatment) or by a CVD method or by combining the oxidation treatment and the CVD method. The oxidation treatment may be ISSG (In-Situ Steam Generation) oxidation. The silicon nitride film NT can be formed, for example, by a CVD method.

In the present embodiment, a memory cell is formed and, as an insulation film (charge accumulation layer) having a trap level, a silicon nitride film NT is formed. A silicon nitride film is suitable for use as a charge accumulation layer, for example, in terms of reliability, but an alternative film may also be used. For example, a film with a dielectric constant higher than that of the silicon nitride film (a high-dielectric-constant insulation film) such as an aluminum oxide film (alumina), hafnium oxide film or tantalum oxide film may be used as a charge accumulation layer or a charge accumulation part.

The silicon oxide film OX1 may be, for example, about 2 to 10 nm thick. The silicon nitride film NT may be, for example, about 5 to 15 nm thick. The silicon oxide film OX2 may be, for example, about 2 to 10 nm thick.

Next, a polycrystalline silicon film PS2 is formed, for example, by a CVD method all over the main surface of the semiconductor substrate SB so as to cover the surface of the ONO film ON. As a result, the side walls and upper surface of the ONO film ON that have been exposed in the memory cell area 1A are covered with the silicon film PS2. Namely, the side walls of the control gate electrode CG are covered with the silicon film PS2 via the ONO film ON.

The silicon film PS2 is, for example, 40 nm thick. In the forming process, the silicon film PS2 may be first formed as an amorphous silicon film to be then changed into a polycrystalline silicon film by heat treatment. The silicon film PS2 is a film into which a relatively high concentration of p-type impurities (e.g. boron (B)) have been introduced. The silicon film PS2 is used to form a memory gate electrode MG being described later.

The film thicknesses referred to in this application represent the film thicknesses in the directions perpendicular to the base surfaces over which the respective films are formed. For example, when the silicon film PS2 is formed over a surface extending, like the upper surface of the ONO film ON, along the main surface of the semiconductor substrate SB, the thickness of the silicon film PS2 is in the direction perpendicular to the main surface of the semiconductor substrate SB. Also, when the silicon film PS2 is formed such that a portion of the silicon film PS2 is in contact with a wall vertical, like the side walls of the ONO film ON, to the main surface of the semiconductor substrate SB, the portion of the silicon film PS2 has a thickness in the direction perpendicular to the side wall.

Though, in FIG. 3, the ONO film ON having a three-layer stack structure including the silicon oxide film OX1, silicon nitride film NT and silicon oxide film OX2 is shown, in the sectional views referred to in the following description, the three-layer stack structure of the ONO film ON is not shown. This is to make the sectional views easier to understand. Namely, even though the ONO film ON has a stack structure, in the sectional views referred to in the following description, the ONO film ON is shown as a single-layer film and the film layer boundaries inside the ONO film ON are not shown.

Next, as shown in FIG. 4, the upper surface of the ONO film ON is exposed by etching back (etching, dry etching, anisotropic etching) the silicon film PS2 using an anisotropic etching technique. In the etch-back process, by anisotropically etching (etching back) the silicon film PS2, the silicon film PS2 is left to be like a side wall formed, via the ONO film ON, on each side of the film stack formed of the gate insulation films GI and IF2 and the control gate electrode CG.

As a result, the memory gate electrode MG is formed in the memory cell area 1A. The memory gate electrode MG is formed of the silicon film PS2 left to be like the side wall formed on one side of the film stack via the ONO film ON. Also, as a result of the above etch-back process, the upper surface of the ONO film ON in the peripheral circuit area 1B is exposed.

Subsequently, a resist film (not shown) is formed over the semiconductor substrate SB using a photolithography technique such that the resist film covers the memory gate electrode MG adjacent to the side wall on one side of the control gate electrode CG while exposing the silicon film PS2 adjacent to the side wall on the other side of the control gate electrode CG. After this, the silicon film PS2 formed on the side opposite to the memory gate electrode MG of the control gate electrode CG is removed by etching performed using the resist film as an etching mask. The resist film is subsequently removed. In the etching process, the memory gate electrode MG being covered with the resist film is left unetched.

Subsequently, the portion exposed without being covered with the memory gate electrode MG of the ONO film ON is removed by etching (e.g. wet etching). At this time, the portion directly below the memory gate electrode MG of the ONO film ON is left unremoved. The portion between the film stack including the gate insulation films GI and IF2 and control gate electrode CG and the memory gate electrode MG of the ONO film ON is also left unremoved. The portions in the other regions of the ONO film ON are removed, so that the upper surface of the semiconductor substrate SB in the memory cell area 1A, the upper surface of the above film stack and the upper surface of the silicon film PS1 in the peripheral circuit area 1B are exposed. The side wall not adjacent to the memory gate electrode MG of the control gate electrode CG is exposed.

As described above, over the semiconductor substrate SB, the memory gate electrode MG is formed to be adjacent to the control gate electrode CG via the ONO film ON having an internal charge accumulation part.

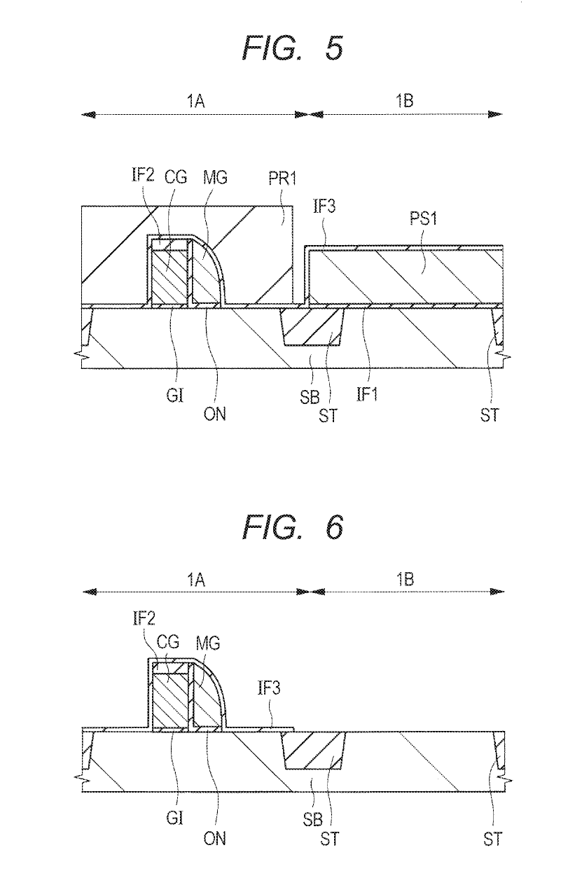

Next, as shown in FIG. 5, an insulation film IF3 is formed all over the main surface of the semiconductor substrate SB, for example, by a CVD method. The insulation film IF3 is, for example, a silicon nitride film. As a result, the silicon film PS1 formed in the peripheral circuit area 1B is covered with the insulation film IF3. In the memory cell area 1A, the film stack including the gate insulation film GI, control gate electrode CG and insulation film IF2, the ONO film ON adjoining the side wall on one side of the film stack, the memory gate electrode MG, and the main surface of the semiconductor substrate SB are covered with the insulation film IF3. Though not illustrated, before forming the insulation film IF3, a silicon oxide film may be deposited all over the main surface of the semiconductor substrate SB, for example, by a CVD method.

Subsequently, using a photolithography technique, a resist film PR1 to cover the insulation film IF3 in the memory cell area 1A is formed. The insulation film IF3 in contact with the upper surface and side wall of the silicon film PS1 is exposed from the resist film PR1.

Next, as shown in FIG. 6, the insulation film IF3 exposed from the resist film PR1 is removed by a wet-etching method, then the resist film PR1 is removed. In this way, the insulation film IF3 in the peripheral circuit area 1B is removed causing the silicon film PS1 and the insulation film IF1 to be exposed.

Subsequently, the silicon film PS1 and the insulation film IF1 in the peripheral circuit area 1B are removed, for example, by a wet-etching method. At this time, in the memory cell area 1A, the film stack including the gate insulation film GI, control gate electrode CG and insulation film IF2, the ONO film ON adjoining the side wall on one side of the film stack and the memory gate electrode MG being covered with the insulation film IF3 are not removed.

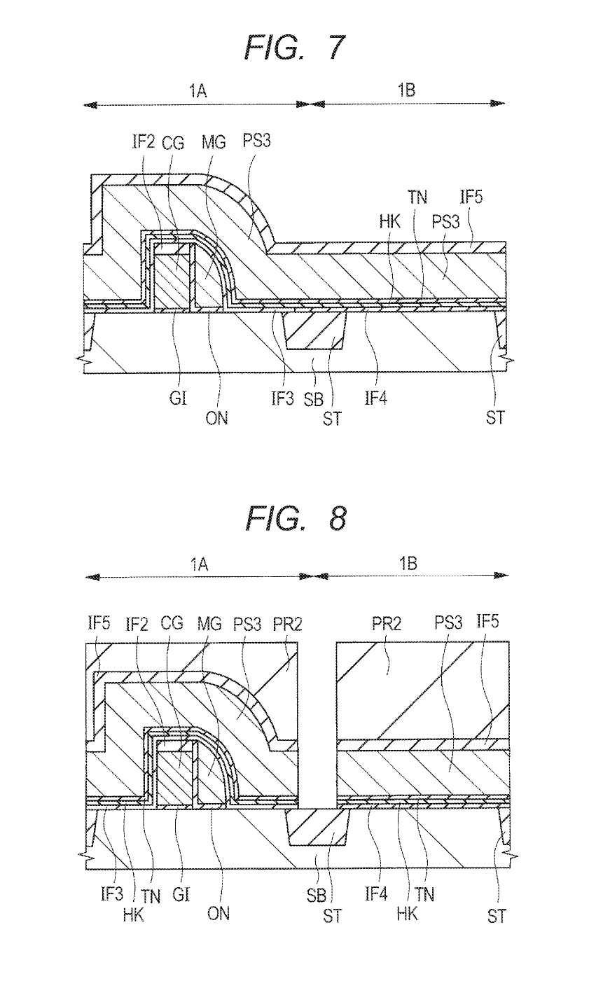

Next, as shown in FIG. 7, insulation films IF4 and HK, a metal film TN, a silicon film PS3 and an insulation film IF5 are formed in this order all over the main surface of the semiconductor substrate SB. As a result, in the memory cell area 1A, the film stack including the gate insulation film GI, control gate electrode CG and insulation film IF2, the ONO film ON adjoining the side wall on one side of the film stack and the memory gate electrode MG are covered with the insulation films IF3, IF4 and HK, the metal film TN, the silicon film PS3 and the insulation film IF5.

The insulation film IF4 is, for example, a silicon oxide film and can be formed by an oxidation method, for example, a thermal oxidation method. The insulation film HK is for gate insulation. To be specific, the insulation film HK is to make up a gate insulation film for the MISFET to be formed in the peripheral circuit area 1B later. The insulation film HK is a so-called high-k film (a high-dielectric-constant film) with a dielectric constant (a specific dielectric constant) higher than those of silicon oxide and silicon nitride.

The insulation film HK may be a metal oxide film, for example, a hafnium oxide film, a zirconium oxide film, an aluminum oxide film, a tantalum oxide film, or a lanthanum oxide film. Such metal oxide films can further contain nitrogen (N) or/and silicon. The insulation film HK can be formed, for example, by an ALD (Atomic Layer Deposition) method. The insulation film HK is, for example, 1.5 nm thick. When forming a high-dielectric-constant film as a gate insulation film (the insulation film HK in the present case), the gate insulation film can be made physically thicker than when the gate insulation film is formed of a silicon oxide film. This is an advantage in that leak current can be reduced.

The metal film TN is, for example, a titanium nitride film and can be formed, for example, by a sputtering method. The silicon film PS3 is a polysilicon film and can be formed, for example, by a CVD method. The silicon film PS3 is, for example, 40 nm thick. When forming the silicon film PS3, the silicon film PS3 may be first formed as an amorphous silicon film to be then changed into a polycrystalline silicon film by heat treatment. The silicon film PS3 is a film into which a relatively high concentration of p-type impurities (e.g. boron (B)) have been introduced. The silicon film PS3 is used to form a dummy gate electrode DG being described later. The insulation film IF5 is a cap insulation film formed of, for example, silicon nitride. The insulation film IF5 can be formed, for example, by a CVD method.

Next, as shown in FIG. 8, a patterned resist film PR2 is formed using a photolithography technique. The resist film PR2 is for exposing the semiconductor substrate SB and element isolation region ST near the boundary between the memory cell area 1A and the peripheral circuit area 1B. After formation of the resist film PR2, the insulation film IF5, silicon film PS3, metal film TN, and insulation films HK and IF4 are removed by etching carried out using the resist film PR2 as a mask. As a result, the silicon film PS3 in the memory cell area 1A and the silicon film PS3 in the peripheral circuit area 1B are separated from each other.

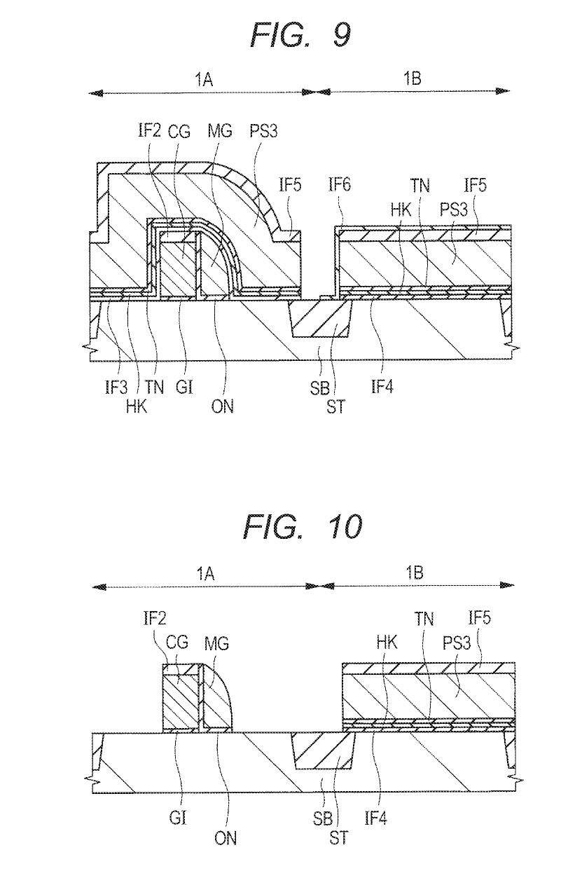

Next, as shown in FIG. 9, after the resist film PR2 is removed, an insulation film IF6 is formed all over the main surface of the semiconductor substrate SB, for example, by a CVD method. The insulation film IF6 is a cap insulation film formed of, for example, a silicon oxide film. Subsequently, the insulation film IF6 in the memory cell area 1A is removed using a photolithography technique and an etching method. As a result, the memory cell area 1A is exposed from the insulation film IF6 and, in the peripheral circuit area 1B, the insulation films IF4 and HK, metal film TN, silicon film PS3 and insulation film IF5 are left covered with the insulation film IF6.

Next, as shown in FIG. 10, in the memory cell area 1A, the insulation film IF5 and the silicon film PS3 are removed using phosphoric acid, then the metal film TN and the insulation films HK and IF3 are removed. At this time, the structure formed over the semiconductor substrate SB in the peripheral circuit area 1B being covered with the resist film is not removed. As a result, in the memory cell area 1A, the film stack including the gate insulation film GI, the control gate electrode CG and the insulation film IF2, the ONO film ON adjoining the side wall on one side of the film stack, and the main surface of the semiconductor substrate SB are exposed. Subsequently, the insulation film IF6 in the peripheral circuit area 1B is removed.

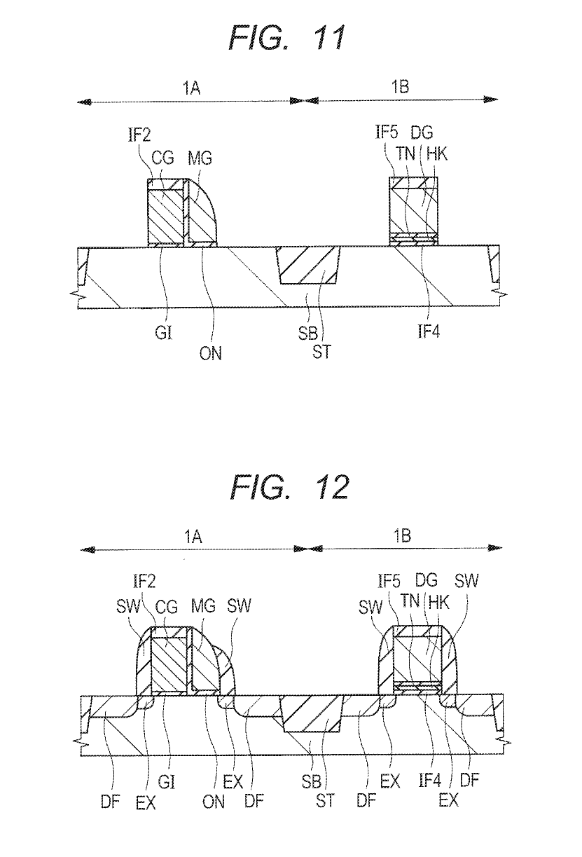

Next, as shown in FIG. 11, in the peripheral circuit area 1B, the insulation film IF5, silicon film PS3, metal film TN, and insulation films HK and IF4 are patterned using a photolithography technique and an etching technique. As a result, a dummy gate electrode DG formed of the silicon film PS3 and a gate insulation film formed of the insulation films HK and IF4 are formed in the region where MISFETs to configure peripheral circuits are formed. For this patterning, first, the insulation film IF5 is patterned using a photolithography technique and an etching method, then, in a state with the memory cell area 1A covered with the resist film, the silicon film PS3, metal film TN and insulation films HK and IF4 are patterned by etching using the insulation film IF5 as a mask.

Next, as shown in FIG. 12, plural extension regions (n⁻ type semiconductor regions, impurity diffusion regions) EX are formed, for example, by an ion implantation method. For example, to form the extension regions, n-type impurities such as arsenic (As) or phosphorus (P) are introduced into the semiconductor substrate SB by an ion implantation method using the gate insulation film GI, control gate electrode CG, memory gate electrode MG, dummy gate electrode DG and ONO film ON as masks. Or, before forming the extension regions EX, offset spacers to respectively cover the side walls of the structure that includes the gate insulation film GI, control gate electrode CG, insulation film IF2 and ONO film ON and the side walls of the dummy gate electrode DG may be formed using a silicon nitride film, a silicon oxide film, or a film stack including such films.

Though the extension regions EX in the memory cell area 1A and the peripheral circuit area 1B can be formed in a same ion implantation process, but it is also possible to form the extension regions EX in the memory cell area 1A and the peripheral circuit area 1B in different ion implantation processes, respectively. Also, though not illustrated, before or after the process for forming the extension regions EX, a halo region may be formed, for example, by implanting p-type impurities (e.g. boron (B)) into the main surface of the semiconductor substrate SB in the peripheral circuit area 1B using the insulation film IF5 and the dummy gate electrode DG as masks. The halo region is formed in a portion of the main surface of the semiconductor substrate SB, the portion, compared with the extension regions EX in the peripheral circuit area 1B, being immediately below a center portion of the dummy gate electrode DG, that is, to be close to the channel region of the MISFET to be formed in the peripheral circuit area 1B in a later process. Forming the halo region improves short-channel characteristics of the MISFET.

Subsequently, side walls SW to cover the side walls on both sides of the above structure including the control gate electrode CG and the gate electrode MG in the memory cell area 1A are formed. In the same process, side walls SB to cover the film stack including the insulation film IF4, insulation film HK, metal film TN, dummy gate electrode DG and insulation film IF5 in the peripheral circuit area 1B are also formed.

The side walls SW can be self-aligningly formed by forming, for example, a silicon oxide film and a silicon nitride film in this order over the semiconductor substrate SB, for example, by a CVD method, then exposing the upper surfaces of the semiconductor substrate SB and the insulation films IF2 and IF5 by partly removing the silicon oxide film and the silicon nitride film by anisotropic etching. Namely, the side walls SW are considered to be formed of laminated films, but, in attached drawings, the side walls SW are shown without any boundaries between the laminated films.

Subsequently, diffusion regions (n⁺ type semiconductor regions, impurity diffusion regions) DF are formed in both the memory cell area 1A and the peripheral circuit area 1B, for example, by an ion implantation method. The impurity diffusion regions DF can be formed by introducing n-type impurities (e.g. arsenic (As) or phosphorus (P)) into the semiconductor substrate SB by an ion implantation method using the gate insulation film GI, control gate electrode CG, insulation film IF2, ONO film ON, memory gate electrode MG, dummy gate electrode DG and side walls SW as masks (masks to block ion implantation). The diffusion regions DF have a higher impurity concentration and a greater junction depth than the extension regions EX.

As a result of the above processing, source and drain regions are formed. The source and drain regions include the extension regions EX and the diffusion regions DF being higher in impurity concentration than the extension regions EX and have an LDD (Lightly Doped Drain) structure.

In the memory cell area 1A, the extension regions EX and the diffusion regions DF formed in upper surfaces of semiconductor substrate SB portions beside the structure that includes the control gate electrode CG and the memory gate electrode MG make up the source and drain regions of the control transistor and the memory transistor being formed later in the memory cell area 1A. Also, in the peripheral circuit area 1B, the extension regions EX and the diffusion regions DF formed in upper surfaces of semiconductor substrate SB portions beside the dummy gate electrode DG make up the source and drain regions of the MISFET being formed later in the peripheral circuit area 1B. The diffusion regions DF in the memory cell area 1A and the peripheral circuit area 1B can be formed in a same ion implantation process, but it is also possible to form the diffusion regions DF in the memory cell area 1A and the peripheral circuit area 1B in different ion implantation processes, respectively.

Subsequently, activation annealing is performed. This is heat treatment to activate the impurities introduced into the source and drain semiconductor regions (extension regions EX and diffusion regions DF). As a result, a structure as shown in FIG. 12 is obtained.

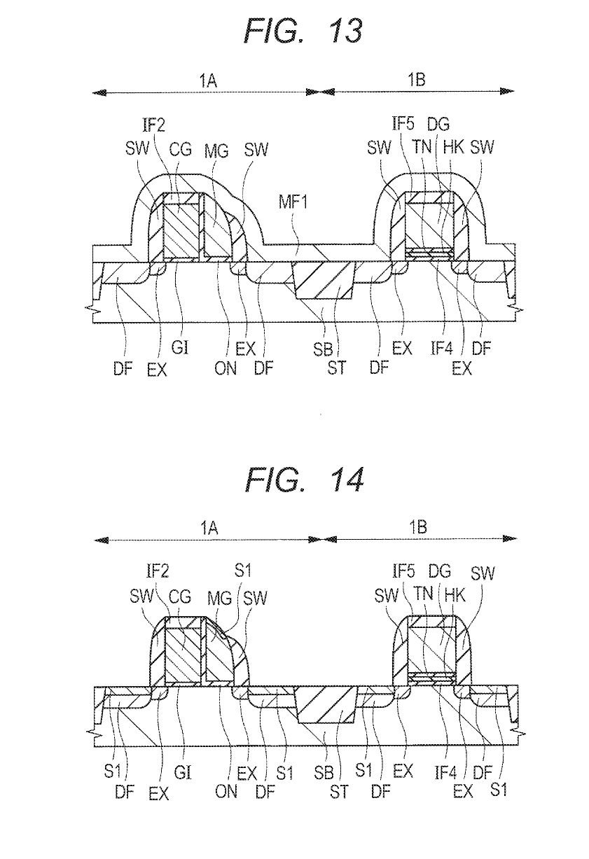

Next, as shown in FIGS. 13 and 14, a silicide layer is formed by performing a so-called salicide (Self-Aligned Silicide) process. To be specific, the silicide layer can be formed as follows.

Namely, as shown in FIG. 13, as preprocessing, the semiconductor surface is exposed by performing chemical dry etching on the main surface of the semiconductor substrate SB, thereby, removing unrequired silicon oxide film from over the semiconductor substrate SB. Subsequently, a metal film MF1 for forming a silicide layer is formed (deposited) all over the main surface of the semiconductor substrate SB including the upper surfaces of the diffusion regions DF and the memory gate electrode MG. The metal film MF1 is, for example, 20 to 25 nm thick.

The metal film MF1 is formed of, for example, an alloy film of nickel (Ni) and platinum (Pt) and can be formed by a sputtering method. The material to be added to nickel to form the alloy film need not necessarily be platinum. For example, aluminum (Al) or carbon (C) may be added to nickel. However, platinum being more heat-resistant than aluminum and carbon can be suitably added to nickel to form the alloy film. The main component of the metal film MF1 may be cobalt (Co) instead of nickel.

Next, as shown in FIG. 14, by heat-treating the semiconductor substrate SB, surface layer portions of the diffusion regions DF and the memory gate electrode MG are made to react with the metal film MF1. This reaction, i.e. silicidation, causes a silicide layer S1 to be formed over the diffusion regions DF and the memory gate electrode MG. The metal film MF1 portions having shown no reaction in the above heat treatment are removed, for example, by wet etching.

For the heat treatment, heat treatment equipment for heating the semiconductor substrate using a carbon heater is used. The heat treatment is performed in the first and second heat treatment processes. In the first heat treatment process, by heating the semiconductor substrate, for example, at 260° C. for 30 to 120 seconds, a silicide layer S1 containing fine NiSi crystal and Ni₂Si is formed. Subsequently, after the metal film MF1 portions having shown no reaction are removed, for example, by wet etching as stated above, the second heat treatment process is performed in which the semiconductor substrate is heated at 600° C. for 5 to 30 seconds so as to cause NiSi crystal growth in the silicide layer S1. Processing the semiconductor substrate through two times of heat treatment as described above prevents the silicide layer S1 from abnormally growing and stretching in the semiconductor substrate SB. The silicide layer S1 formed in the above manner includes, for example, nickel platinum (NiPt) silicide.

Note that the upper surface of the control gate electrode CG is covered with the insulation film IF2 that is a cap film, so that the silicide layer S1 is not formed over the upper portion of the control gate electrode CG. Similarly, the upper portion of the dummy gate electrode DG is covered with the insulation film IF5 that is a cap film, so that the silicide layer S1 is not formed over the upper portion of the dummy gate electrode CG. An upper portion of the memory gate electrode MG formed like a side wall is exposed, so that the silicide layer S1 is formed over the exposed portion. However, the silicide layer S1 formed over the upper portion of the memory gate electrode MG is later removed in a polishing process performed by a CMP (Chemical Mechanical Polishing) method.

In cases where the insulation films IF2 and IF5 are not formed, the silicide layer S1 is also formed over the upper surfaces of the control gate electrode CG and dummy gate electrode DG. The silicide layer S1 formed over the upper surfaces of the control gate electrode CG and dummy gate electrode DG is also removed in the above polishing process. The silicide layer S1 is formed to be in contact with the upper surfaces of the diffusion regions DF. Namely, the silicide layer S1 is formed to be in contact with the upper surfaces of the source and drain regions.

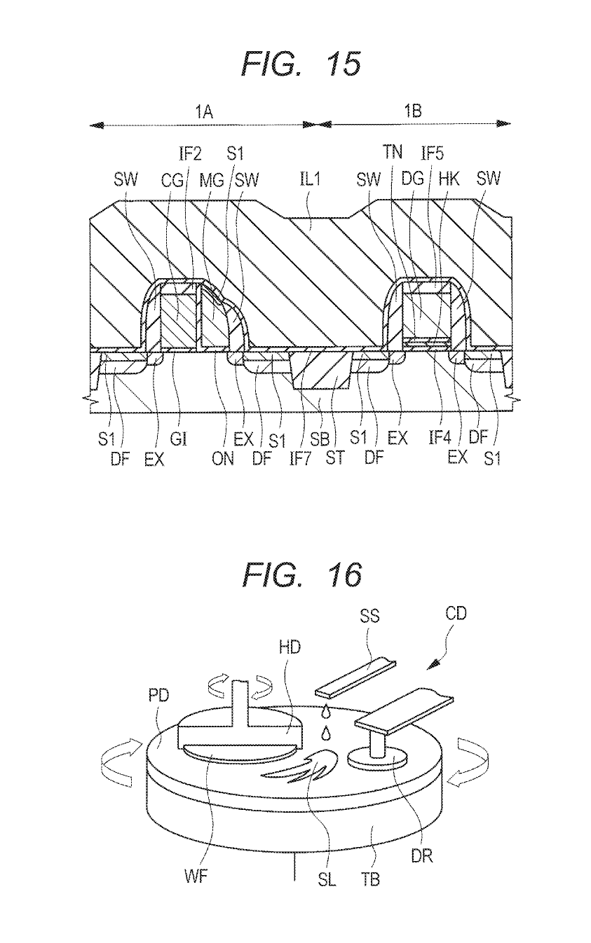

Next, as shown in FIG. 15, an insulation film (liner insulation film, etching stopper film) IF7 and an interlayer insulation film IL1 are formed in this order all over the main surface of the semiconductor substrate SB so as to cover the control gate electrode CG, the memory gate electrode MG, the dummy gate electrode DG and the side walls SW. The insulation film IF7 is, for example, a silicon nitride film and can be formed, for example, by a CVD method. The insulation film IF7 can be used as an etching stopper film when contact holes are formed in a later process. The interlayer insulation film IL1 is, for example, a single silicon oxide film and can be formed, for example, by a CVD method. The interlayer insulation film IL1 is thicker than the insulation film IF7. In the present case, the interlayer insulation film IL1 is formed to be thicker than, for example, the control gate electrode CG.

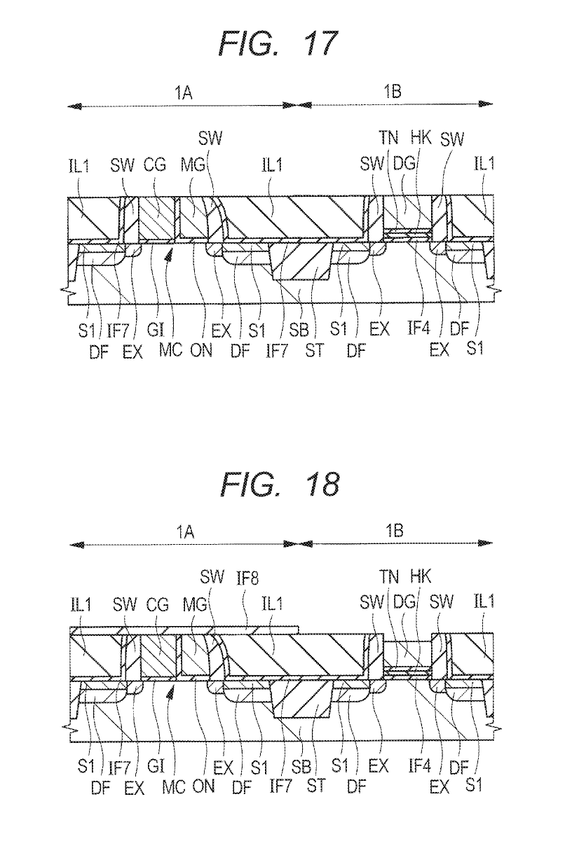

Next, as shown in FIG. 17, the upper surface of the interlayer insulation film IL1 is polished by a CMP method using a polishing apparatus CD shown in FIG. 16. The CMP method is performed using a polishing slurry containing not alkaline aqueous solution (alkaline solvent) but acidic aqueous solution (acid solvent) which contains hydrogen peroxide (H₂O₂) or hydrochloric acid (HCl). This polishing process is for exposing the dummy gate electrode DG to be replaced by a metal gate electrode later. The slurry has a pH of, for example, 3.

The polishing apparatus CD (see FIG. 16) used in the above polishing process has a flat table TB, a polishing pad PD positioned in contact with the upper surface of the flat table TB, a dresser DR positioned on the polishing pad PD, a head HD positioned on the polishing pad PD and a slurry supply part SS positioned on the polishing pad PD. The head HD, flat table TB and polishing pad PD are each circular as seen from above. The flat table TB and the polishing pad PD are concentric. In a planar view, the head HD is smaller than the polishing pad PD. In FIG. 16, only the head HD is shown in a sectional view.

The slurry supply part SS is a device to supply slurry SL, which is a polishing agent, over the upper surface of the polishing pad PD in the polishing process. The dresser DR is a pad conditioner to condition the upper surface of the polishing pad PD. In the polishing process, the flat table TB rotates, together with the polishing pad PD, about the common central axis of the two parts. In the polishing process, a semiconductor wafer WF is polished by being positioned upside down between the bottom surface of the rotating head HD and the rotating polishing pad PD and, in that state, by being pressed by the head HD against the upper surface of the polishing pad PD. The semiconductor wafer WF shown in FIG. 16 is equivalent to the semiconductor substrate SB shown in FIG. 15.

In the present case, hydrogen peroxide (H₂O₂) or hydrochloric acid (HCl) is mixed with a slurry beforehand and the slurry containing acidic aqueous solution is supplied from the slurry supply part SS as shown in FIG. 16.

After being polished in the polishing process, the semiconductor wafer (semiconductor substrate) is conveyed to a cleaning apparatus where the surface of the semiconductor substrate is cleaned. The semiconductor substrate is subsequently dried. When the semiconductor substrate is conveyed from the polishing apparatus to the cleaning apparatus, the semiconductor substrate is kept being supplied with moisturizing water so as to keep the surface of the semiconductor substrate moist during the conveyance. The moisturizing water is required to have a positive oxidation-reduction potential.

In the above cleaning process, the first cleaning process and the second cleaning process are performed in order. The first cleaning process is mainly for removing metal or metal ions left, as a result of polishing, over the surface of the semiconductor substrate and is performed using a weakly acidic chemical solution (acidic aqueous solution). The second cleaning process is mainly for removing abrasive grains left as a result of polishing and is performed using pure water. In the first process, metal ions left after the polishing process is removed from the surface of the semiconductor substrate by using not an alkaline solution (e.g. ammonia water) but an acidic chemical solution (acidic aqueous solution). The acidic chemical solution may be, for example, oxalic acid ((COOH)₂) or citric acid ((CH₂COOH)₂COOH). In cases where the chemical solution used for cleaning the semiconductor substrate is allowed to be strongly acidic, dilute hydrofluoric acid (DHF) may be used as the chemical solution.

In the present case, a weakly acidic chemical solution is used to suppress effects on the films formed over the substrate. Using a relatively strongly acidic chemical solution, for example, hydrogen fluoride (hydrofluoric acid (HF)) for cleaning the semiconductor substrate may cause the interlayer insulation film and other films formed over the semiconductor substrate to be excessively removed, resulting in impairing the film flatness over the semiconductor substrate. This can be prevented by using a weakly acidic chemical solution in the first cleaning process.

In the polishing process, the upper surfaces of the control gate electrode CG, memory gate electrode MG and dummy gate electrode DG shown in FIG. 17 are exposed from the interlayer insulation film IL1, insulation films IF2, IF5 and IF7, and silicide layer S1. Namely, in the polishing process, the interlayer insulation film IL1, insulation films IF2, IF5 and IF7, and silicide layer S1 are polished until the upper surfaces of the control gate electrode CG, memory gate electrode MG and dummy gate electrode DG are exposed. As a result, the insulation films IF2 and IF5 are removed and, also, the upper portions of the interlayer insulation film IL1, insulation film IF7, side walls SW and ONO film ON are partly removed. Also, the silicide layer S1 over the memory gate electrode MG is removed in the same process together with an upper portion of the memory gate electrode MG. Namely, the silicide layer S1 is not left over the upper surface of the memory gate electrode MG.

The shapes of the control gate electrode CG and memory gate electrode MG are thus processed and, as a result, a memory cell of a split-gate type MONOS memory is formed in the memory cell area 1A with the memory cell including the control gate electrode CG, the ONO film ON, the memory gate electrode MG and the source and drain regions. The memory cell MC that is a MONOS-type non-volatile memory element includes a control transistor and a memory transistor.

Namely, in the memory cell area 1A, the control gate electrode CG and a pair of source and drain regions formed in upper surface portions beside the control gate electrode CG of the semiconductor substrate SB make up a control transistor. Also, in the memory cell area 1A, the memory gate electrode MG and a pair of source and drain regions formed in upper surface portions beside the memory gate electrode MG of the semiconductor substrate SB make up a memory transistor. Also, the ONO film ON directly below the memory gate electrode MG makes up the gate insulation film of the memory transistor. Thus, the control transistor and the memory transistor share a pair of source and drain regions.

The control transistor being for memory cell selection can be regarded as a selection transistor. Hence the control gate electrode CG can be regarded as a selection gate electrode. The memory transistor is a memorization transistor.

Next, as shown in FIG. 18, after forming an insulation film IF8 over the interlayer insulation film IL1, for example, by a CVD method, the insulation film IF8 in the peripheral circuit area 1B is removed using a photolithography technique and an etching method. As a result, the insulation film IF8 is left only in the memory cell area 1A. Namely, the upper surfaces of the control gate electrode CG and the memory gate electrode MG are covered with the insulation film IF8, whereas the upper surface of the dummy gate electrode DG is exposed. The insulation film IF8 is, for example, a silicon oxide film.

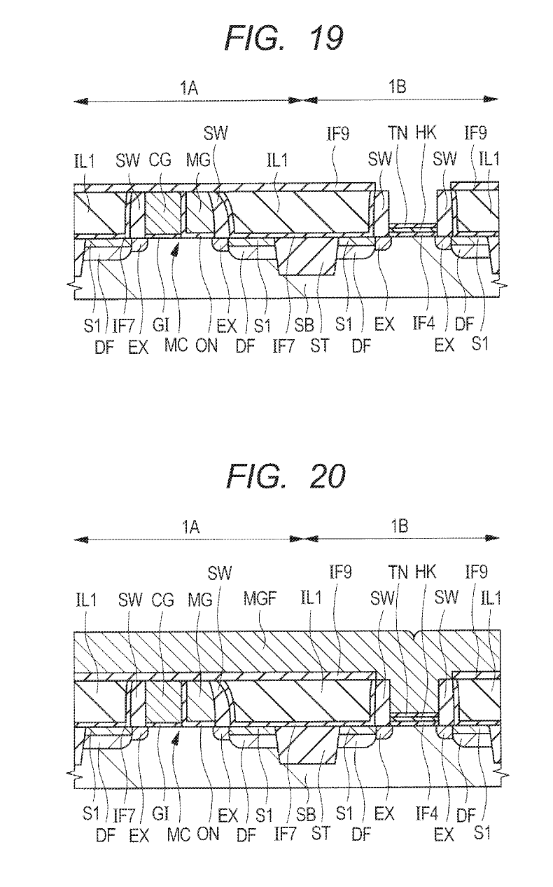

Subsequently, the upper surface exposed from the insulation film IF8 of the dummy gate electrode DG in the peripheral circuit area 1B is etched back to be lowered. Thus, by partly removing the upper portion of the dummy gate electrode DG, the film formed over the upper surface of the dummy gate electrode DG can be removed. Therefore, in the etching process being described later with reference to FIG. 19, the dummy gate electrode DG can be easily removed.

Next, as shown in FIG. 19, after forming an insulation film IF9 over the interlayer insulation film IL1, for example, by a CVD method, the insulation film IF9 is processed using a photolithography technique and an etching method. As a result, the insulation film IF9 covers the memory cell area 1A and the interlayer insulation film IL1 in the peripheral circuit area 1B. Namely, the upper surfaces of the control gate electrode CG and memory gate electrode MG are covered with the insulation film IF9, whereas the upper surface of the dummy gate electrode DG is exposed. The insulation film IF9 is, for example, a silicon oxide film. Though not illustrated, the insulation film IF8 (see FIG. 18) may be left, without being removed, between the insulation film IF9 and the interlayer insulation film IL1.

Subsequently, the dummy gate electrode DG is removed by a wet-etching method. In the present case, wet etching to remove the dummy gate electrode DG is performed using, for example, an alkaline aqueous solution and also using the insulation film IF9 as a mask to protect the control gate electrode CG and the memory gate electrode MG. The alkaline aqueous solution may be, for example, ammonia water (NH₄OH). With the dummy gate electrode DG removed, a groove (an concave or depressed portion) is formed over the insulation films IF4 and HK making up a gate insulation film. The groove formed over the insulation film HK in the peripheral circuit area 1B represents a region from which the dummy gate electrode DG has been removed and the groove has the side walls SW on both sides.

Next, as shown in FIG. 20, a metal film MGF is formed as a conducting film for the gate electrode over the semiconductor substrate SB, that is, over the interlayer insulation film IL1 including the inner surfaces (bottom and side-wall surfaces) of the above groove such that the groove is completely filled. Though the metal film MGF is considered to have a multilayer structure including two or more metal films, it is shown, in FIG. 20, as a metal film MGF without any inner metal film boundaries shown.

In the process of forming the metal film MGF, the groove is completely filled. The metal film MGF is also formed over the interlayer insulation film IL1. The metal film MGF may be formed of, for example, a titanium nitride (TiN) film, a tantalum nitride (TaN) film, a tungsten nitride (WN) film, a titanium carbide (TiC) film, a tantalum carbide (TaC) film, a tungsten carbide (WC) film, a tantalum carbon nitride (TaCN) film, a titanium (Ti) film, a tantalum (Ta) film, a titanium aluminum (TiAl) film, or an aluminum (Al) film. The metal film referred to in this application represents a conducting film having metallic conductivity which may be a single-metal film (pure-metal film), an alloy film, or even a metal compound film having metallic conductivity.

In the present case, the metal film MGF can be formed, for example, as a stack of a titanium nitride (TiN) film and an aluminum (Al) formed over the titanium nitride film. In the film stack, the aluminum film is preferably thicker than the titanium nitride film. The aluminum film being low in resistance can reduce the resistance of the gate electrode G1 to be formed later. The aluminum film is made by a PVD (Physical Vapor Deposition) method, i.e. by sputtering.

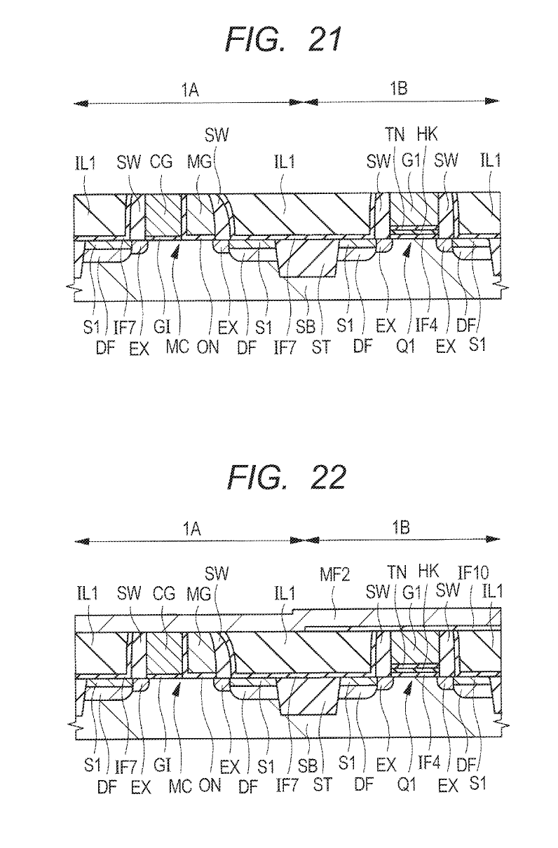

Next, as shown in FIG. 21, the unnecessary portions outside the groove of the metal film MGF and the insulation film IF9 are removed by polishing performed, for example, by a CMP method without removing the metal film MGF filled in the groove. As a result, the control gate electrode CG and the memory gate electrode MG are exposed from the metal film MGF and the insulation film IF9. If the insulation film IF8 (see FIG. 18) is still left, the insulation film IF8 is also removed.

The gate electrode G1 is formed by the metal film MGF filled in the groove over the insulation film IF4 in the peripheral circuit area 1B. As a result, a MISFET Q1 is formed in the peripheral circuit area 1B. The MISFET Q1 includes the gate electrode G1 and the source and drain regions beside it. The MISFET Q1 is, for example, a field-effect transistor making up a circuit peripheral to the memory cell MC.

The insulation films HK and IF4 directly below the gate electrode G1 make up a gate insulation film of the MISFET Q1. The gate electrode G1 is a metal gate electrode. In the present embodiment, the dummy gate electrode DG (see FIG. 18) is removed and the gate electrode G1 is formed in place of the dummy gate electrode DG. Namely, the dummy gate electrode DG is a pseudo-gate electrode formed to be replaced later.

As described above, in the present embodiment, the MISFET Q1 is formed using a gate last process, that is, a method in which, after the dummy gate electrode DG is formed over the semiconductor substrate SB and source and drain regions are formed in the semiconductor substrate SB, the dummy gate electrode DG is replaced by a metal gate electrode. Also, in the present embodiment, with the gate electrode G1 being a metal gate electrode, the transistor element can be made smaller (with a thinner gate insulation film).

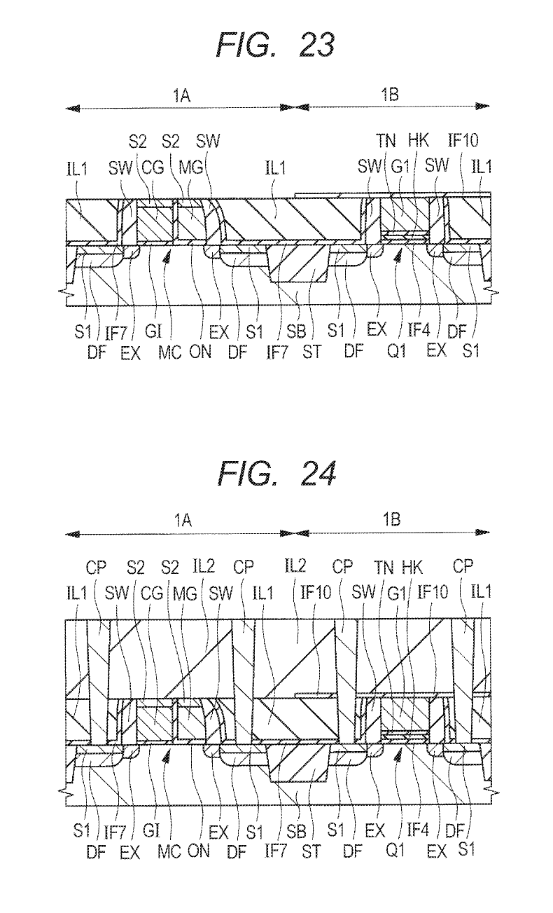

Next, as will be described with reference to FIGS. 22 and 23, by a salicide process, a silicide layer is formed over each electrode formed of a polysilicon film. To be specific, the silicide layer can be formed as follows.

As shown in FIG. 22, an insulation film IF10 covering the peripheral circuit area 1B is patterned, for example, using a CVD method, a photolithography technique and an etching method. The insulation film IF10 is, for example, a silicon oxide film and covers the gate electrode G1. The upper surfaces of the control gate electrode CG and the memory gate electrode MG in the memory cell area 1A are not covered with the insulation film IF10.

For patterning of the insulation film IF10, after the insulation film IF10 is formed over the interlayer insulation film IL1, for example, by a CVD method, the insulation film IF10 is processed first by dry etching using a resist pattern as a mask (not shown), then by wet etching using hydrofluoric acid (HF). As a result, in the memory cell area 1A, the upper surfaces of the interlayer insulation film IL1, ONO film ON, control gate electrode CG, memory gate electrode MG and side walls SW are exposed.

Subsequently, as preprocessing, by performing chemical dry etching over the main surface of the semiconductor substrate SB, excess silicon oxide films, etc. left on the control gate electrode CG and the memory gate electrode MG are removed. Subsequently, a metal film MF2 for forming a silicide layer is formed (deposited) all over the main surface of the semiconductor substrate SB including the upper surfaces of the control gate electrode CG and the memory gate electrode MG. The metal film MF2 is, for example, 20 to 25 nm thick.

The metal film MF2 is an alloy film containing, for example, nickel (Ni) and platinum (Pt) and can be formed by a sputtering method. The metal film MF2 formed in the present embodiment is an alloy film containing nickel. The material to be added to nickel to form the alloy film need not necessarily be platinum. For example, aluminum (Al) or carbon (C) may be added to nickel. However, platinum which is more heat-resistant than aluminum and carbon can be suitably added to nickel to form the alloy film. In the metal film MF2, platinum (Pt) accounts for 5%. The main component of the metal film MF2 may be cobalt (Co) instead of nickel.

Next, as shown in FIG. 23, by heat-treating the semiconductor substrate SB, surface layer portions of the control gate electrode CG and the memory gate electrode MG are made to react with the metal film MF2. This silicidation causes a silicide layer S2 to be formed over the upper portions of the control gate electrode CG and the memory gate electrode MG. The metal film MF2 portions having shown no reaction in the above heat treatment are removed, for example, by wet etching performed after the heat treatment. When this is done, the metal-film gate electrode G1 covered with the insulation film IF10 is not removed.

For the heat treatment, heat treatment equipment for heating the semiconductor substrate using a carbon heater is used. The heat treatment is performed in the first and second heat treatment processes. In the first heat treatment process, by heating the semiconductor substrate, for example, at 260° C. for 30 to 120 seconds, a silicide layer S2 containing fine NiSi crystal and Ni₂Si is formed. Subsequently, after the metal film MF2 portions having shown no reaction are removed, for example, by wet etching as described above, the second heat treatment process is performed in which the semiconductor substrate is heated at 400° C. for 10 to 120 seconds so as to cause NiSi crystal growth in the silicide layer S2. The silicide layer S2 formed in the above manner contains, for example, nickel platinum (NiPt) silicide.

Next, as shown in FIG. 24, an interlayer insulation film and plural contact plugs (coupling parts) are formed. For this, first, an interlayer insulation film IL2 to entirely cover the upper surface of the semiconductor substrate SB including the memory cell area 1A and the peripheral circuit area 1B is formed, for example, by a CVD method. The interlayer insulation film IL2 is, for example, a silicon oxide film and covers the upper surfaces of the control gate electrode CG, memory gate electrode MG, gate electrode G1 and interlayer insulation film IL1.

Subsequently, the interlayer insulation films IL2 and IL1 and the insulation films IF10 and IF7 are dry-etched using a photolithography technique and also using the resist (not shown) formed over the interlayer insulation film IL2 as a mask. As a result, plural contact holes (openings, through-holes) are formed through the interlayer insulation film IL2 and, also, through the interlayer films IL1 and IL2 and the insulation film IF7. In the peripheral circuit area 1B, contact holes are formed through the insulation film IF10.

At the bottom of each contact hole, a portion of the main surface of the semiconductor substrate SB is exposed. For example, a portion of the silicide layer S1 formed over the surface of a diffusion region DF, a portion of the silicide layer S2 formed over the surface of the control gate electrode CG, a portion of the silicide layer S2 formed over the surface of the memory gate electrode MG, or a portion of the gate electrode G1 is exposed. The contact holes over the respective gate electrodes are formed in regions not shown in FIG. 24.

Subsequently, in each contact hole, a conductive contact plug CP of, for example, tungsten (W) is formed as a conductor for coupling. To form a contact plug CP, a barrier conductive film (e.g. a titanium film, titanium nitride film or a film stack including such films) is formed over the interlayer insulation film IL2 including the interior of the contact hole. Subsequently, a main conductive film including a tungsten film is formed over the barrier conductive film so as to completely fill the contact hole, then unrequired portions outside the contact hole of the main conductive film and barrier conductive film are removed, for example, by a CMP method or an etch back method, thereby completing the contact plug CP. In FIG. 24, for drawing simplification, the barrier conductive film and the main conductive film (tungsten film) forming each contact plug CP are shown as a unified film.

The contact plug CP filled in each contact hole is formed to be in contact with the upper portion of a diffusion region DF, control gate electrode CG, memory gate electrode MG or gate electrode G1. Namely, the upper surfaces of the diffusion regions DF of each of the memory cell MC and the MISFET Q1 are coupled with contact plugs CP via the silicide layer S1. Also, the upper surface of each of the control gate electrode CG and the memory gate electrode MG is coupled with a contact plug CP via the silicide layer S2.

One of the aims of forming the silicide layers S1 and S2 is to reduce the contact resistances between contact plugs CP and diffusion regions DF, the control gate electrode CG and the memory gate electrode MG that are formed of semiconductor. Hence, no silicide layer is formed between the gate electrode G1 that is a metal gate electrode and contact plugs CP.

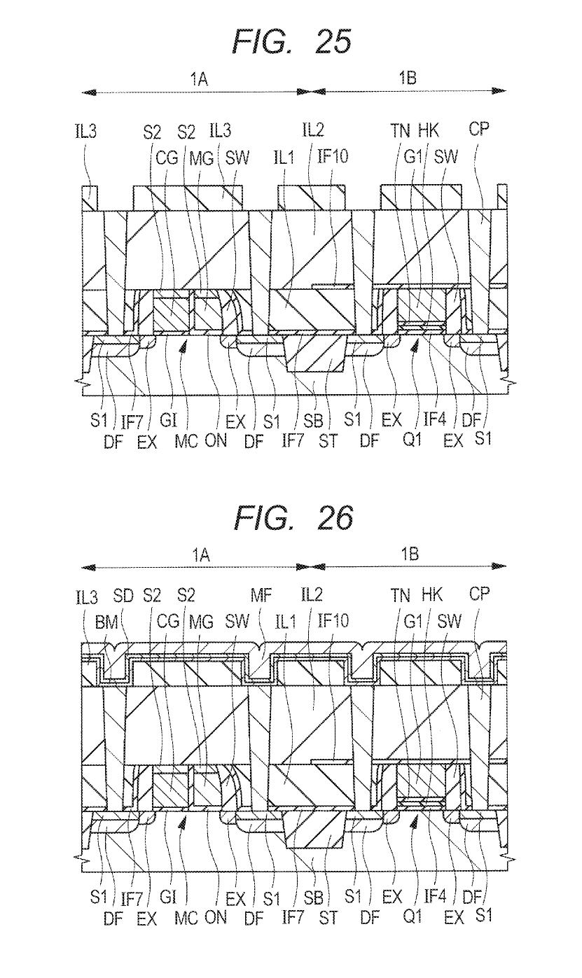

Next, as shown in FIG. 25, an interlayer insulation film IL3 is formed (deposited) over the interlayer insulation film IL2, for example, by a CVD method. The interlayer insulation film IL3 is, for example, a silicon oxide film. Subsequently, the interlayer insulation film IL3 is processed using a photolithography technique and a dry etching method. As a result, openings are formed through the interlayer insulation film IL3, that is, plural grooves (wiring grooves) are formed to expose the upper surfaces of the contact plugs CP.

Next, as shown in FIG. 26, by using a sputtering method, a barrier conductive film BM and a seed film SD are formed in this order over the interlayer insulation films IL2 and IL3 and the contact plugs CP. The barrier conductive film BM and the seed film SD thus formed do not completely fill the grooves formed over the interlayer insulation film IL3. The barrier conductive film BM is formed of, for example, tantalum (Ta) or tantalum nitride (TaN). The seed film SD is formed of copper (Cu). The barrier conductive film BM and the seed film SD are deposited, for example, by a sputtering method.

Subsequently, by using a plating method, a thick main conductive film MF is formed over the seed film SD. The main conductive film MF is formed of, for example, copper (Cu). As a result, the grooves formed over the interlayer insulation film IL3 are completely filled with a film stack formed of the barrier conductive film BM, seed film SD and main conductive film MF.

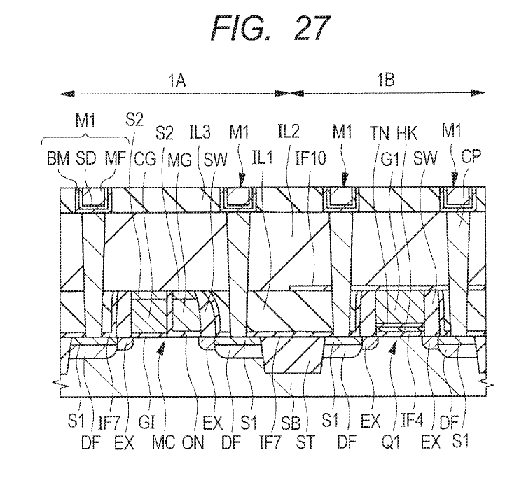

Next, as shown in FIG. 27, excess portions over the interlayer insulation film IL3 of the barrier conductive film BM, seed film SD and main conductive film MF are removed, for example, by a CMP method and, thereby, the upper surface of the interlayer insulation film IL3 is exposed. As a result, wirings M1 are formed by the film stack formed of the barrier conductive film BM, seed film SD and main conductive film MF filled in the grooves (wiring grooves) in the interlayer insulation film IL3. The wirings M1 and the interlayer insulation film IL3 make up a first wiring layer. The barrier conductive film BM serves to prevent the copper contained in the wirings buried in the grooves in the interlayer insulation film IL3 from diffusing into insulation films such as the interlayer insulation film IL3 adjacent to the wirings M1.

The wirings M1 in a first layer are electrically coupled to the upper surfaces of contact plugs CP. Subsequently, a second wiring layer and a third wiring layer are formed in this order over the first wiring layer, then the semiconductor wafer is singulated by dicing into plural semiconductor chips. How the semiconductor device of the present embodiment is manufactured has been described.

<Operations of Non-Volatile Memory>

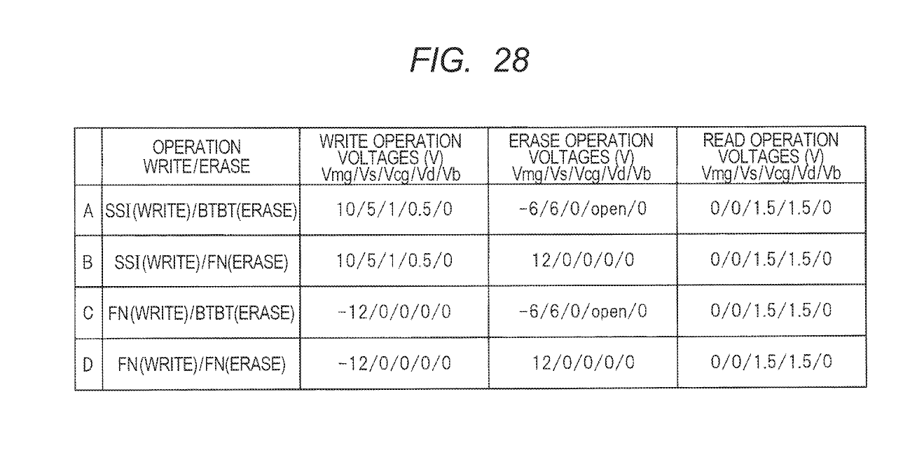

In the following, example operations of the non-volatile memory will be described with reference to FIG. 28.

The memory cell of the present embodiment has a MISFET structure in which the state of charge accumulation in a trap insulating film included in the gate electrode of the MISFET is read as information held in the memory cell representing the threshold of the transistor. The trap insulating film is an insulation film capable of charge accumulation. For example, a silicon nitride film is a trap insulating film. The memory cell operates as a memory element by having charges injected into or discharged from such a charge accumulation region to thereby shift the threshold of the MISFET. A split-gate type MONOS memory like the memory cell of the present embodiment is an example of a non-volatile semiconductor memory device using a trap insulating film.

FIG. 28 is a table listing example voltages to be applied to different parts of a memory cell selected as a target of a “write,” “erase” or “read” operation according to the present embodiment. To be specific, FIG. 28 lists the following voltages to be applied for write, erase, and read operations, respectively: voltage Vmg to be applied to the memory gate electrode MG of the memory cell MC shown in FIG. 27; voltage Vs to be applied to the source region of the memory cell MC; voltage Vcg to be applied to the control gate electrode CG of the memory cell MC; voltage Vd to be applied to the drain region of the memory cell MC; and base voltage Vb to be applied to the p-type well formed in the upper surface of the semiconductor substrate.

In the case of the non-volatile memory shown in FIG. 27, the active region on the right of the memory gate electrode MG is the source region and the active region on the left of the control gate electrode CG is the drain region. The voltages listed in FIG. 28 are example voltages appropriate for application. Namely, the voltages to be applied are not limited to the values listed in FIG. 27 and may be changed as required. Also, for the present embodiment, injection of electrons into the silicon nitride film NT (see FIG. 3) to serve as a charge accumulation part in the ONO film ON formed in the memory transistor is defined as writing (write operation) and injection of holes into the silicon nitride film NT is defined as erasing (erase operation).

In the table of FIG. 28: row A corresponds to when writing is made by a SSI (Source-Side Injection) method and erasing is made by a BTBT (Band-To-Band Tunneling) method; row B corresponds to when writing is made by a SSI method and erasing is made by a FN (Fowler-Nordheim) method; row C corresponds to when writing is made by a FN method and erasing is made by a BTBT method; and row D corresponds to when writing is made by a FN method and erasing is made by a FN method.

The SSI method can be considered to be an operation method for writing information to the memory cell by injecting hot electrons into the silicon nitride film NT. The BTBT method can be considered to be an operation method for erasing information from the memory cell by injecting hot holes into the silicon nitride film NT. The FN method can be considered to be an operation method for writing information to or erasing information from the memory cell by electron or hole tunneling. This can also be described differently as follows. Namely, in writing by the FN method, information is written to the memory cell by injecting electrons into the silicon nitride film NT using an FN tunneling effect and, in erasing by the FN method, information is erased from the memory cell by injecting holes into the silicon nitride film using an FN tunneling effect. These operations will be described more specifically in the following.

For writing, two methods can be used. One of the two methods is the SSI method in which writing is made by injecting hot electrons by source side injection (writing by hot electron injection). The other of the two methods is the FN method in which writing is made by means of tunneling (writing by tunneling).

In writing by the SSI method, voltages, for example, the voltages listed as “write operation voltages” in row A or B of the table shown in FIG. 28 (i.e. Vmg=10 V, Vs=5 V, Vcg=1 V, Vd=0.5 V, Vb=0 V) are applied to the corresponding parts of the memory cell selected as a target of writing and, thereby, electrons are injected into the silicon nitride film NT included in the ONO film ON of the selected memory cell.

At this time, hot electrons are generated in a channel region (between the source and drain regions) located between and below the two gate electrodes (the memory gate electrode MG and the control gate electrode CG). As a result, hot electrons are injected into the silicon nitride film NT serving as a charge accumulation part in the portion below the memory gate electrode MG of the ONO film ON. The hot electrons injected are captured at a trap level in the silicon nitride film NT included in the ONO film ON and, as a result, the threshold voltage of the memory transistor rises. Namely, the memory transistor enters a written state.

In writing by the FN method, voltages, for example, the voltages listed as “write operation voltages” in row C or D of the table shown in FIG. 28 (i.e. Vmg=12 V, Vs=0 V, Vcg=0 V, Vd=0 V, Vb=0 V) are applied to the corresponding parts of the memory cell selected as a target of writing and, thereby, in the selected memory cell, electrons are injected by tunneling from the memory gate electrode MG into the silicon nitride film NT included in the ONO film ON. At this time, by FN tunneling (a FN tunnel effect), electrons tunnel from the memory gate electrode MG through the silicon oxide film OX2 (see FIG. 3) to be injected into the ONO film ON and are then captured at a trap level in the silicon nitride film NT included in the ONO film ON. As a result, the threshold voltage of the memory transistor rises. Namely, the memory transistor enters a written state.

In writing by the FN method, it is also possible to perform writing by making electrons tunnel from the semiconductor substrate SB into the silicon nitride film NT included in the ONO film ON. In this case, the write operation voltages listed in row C or D of the table shown in FIG. 28 can be applied with their polarities reversed.

For erasing, two methods can be used. One of the two methods is the BTBT method in which erasing is made by injecting hot holes through band-to-band tunneling (erasing by hot hole injection). The other of the two methods is the FN method in which erasing is made by means of FN tunneling (erasing by tunneling).

In erasing by the BTBT method, holes generated by means of BTBT are injected into the charge accumulation part (the silicon nitride film NT included in the ONO film ON). For this, voltages, for example, the voltages listed as “erase operation voltages” in row A or C of the table shown in FIG. 28 (i.e. Vmg=−6 V, Vs=6 V, Vcg=0 V, Vd=open, Vb=0 V) are applied to the corresponding parts of the memory cell selected as a target of erasing. This causes a BTBT phenomenon in which holes are generated and are, by means of electric field acceleration, injected into the silicon nitride film NT included in the ONO film ON of the memory cell selected as a target of erasing. As a result, the threshold voltage of the memory transistor is lowered. Namely, the memory transistor enters an erased state.

In erasing by the FN method, voltages, for example, the voltages listed as “erase operation voltages” in row B or D of the table shown in FIG. 28 (i.e. Vmg=12 V, Vs=0 V, Vcg=0 V, Vd=0 V, Vb=0 V) are applied to the corresponding parts of the memory cell selected as a target of erasing and, thereby, in the selected memory cell, holes are injected by tunneling from the memory gate electrode MG into the silicon nitride film NT included in the ONO film ON. At this time, by FN tunneling (a FN tunnel effect), holes tunnel from the memory gate electrode MG through the silicon oxide film OX₂ (see FIG. 3) to be injected into the ONO film ON and are then captured at a trap level in the silicon nitride film NT included in the ONO film ON. As a result, the threshold voltage of the memory transistor lowers. Namely, the memory transistor enters an erased state.

In erasing by the FN method, it is also possible to perform erasing by making holes tunnel from the semiconductor substrate SB into the silicon nitride film NT included in the ONO film ON. In this case, the erase operation voltages listed in row B or D of the table shown in FIG. 28 can be applied with their polarities reversed.

For reading, voltages, for example, the voltages listed as “read operation voltages” in row A, B, C, or D are applied to the corresponding parts of the memory cell selected as a target of reading. Setting the voltage Vmg to be applied to the memory gate electrode MG for reading to a value between the threshold voltage of the memory transistor in a written state and the threshold voltage of the memory transistor in an erased state makes it possible to distinguish between a written state and an erased state.

### Effects of Present Embodiment

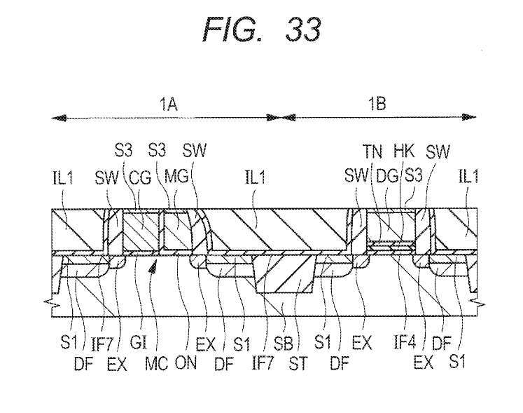

Advantageous effects of the manufacturing method and the semiconductor device according to the present embodiment will be described with reference to FIG. 33 showing an example for comparison. FIG. 33 is a sectional view of a semiconductor device manufacturing process according to the comparison example.

In a MONOS memory, the gate electrode resistance can be reduced by using a silicide layer over the gate electrode as wiring. In cases where the gate electrode of a transistor making up a logic circuit, etc. in a peripheral circuit area is formed by replacing a dummy gate electrode formed of a semiconductor film with a metal gate electrode, it is necessary to use a gate last process.

In the gate last process, after forming a silicide layer over the upper surface of the memory gate electrode and the upper surfaces of the source and drain regions of the transistor, an interlayer insulation film to cover the respective gate electrodes is formed. Subsequently, a polishing process is performed to expose from the interlayer insulation film the dummy gate electrode in the peripheral circuit area and the control gate electrode and the memory gate electrode in the memory cell area. The dummy gate electrode thus exposed is removed, for example, by etching, then a metal gate electrode including a metal film is filled in the groove formed as a result of the etching. This forms a MISFET having a metal gate electrode.

When the above polishing process is performed, it can happen under certain conditions that, after the silicide layer over the gate electrodes is once removed, formation of a silicide layer over the respective gate electrodes occurs when the polishing process is completed. FIG. 33 shows a structure with a thin silicide layer formed, as a result of the polishing process, over the upper surfaces of the dummy gate electrode DG, control gate electrode CG and memory electrode MG. The structure shown in FIG. 33 represents a structure resulting from a polishing process performed, after the process described, for example, with reference to FIG. 15, under conditions different from the conditions according to the present embodiment.

In cases where, as shown in FIG. 33, the upper surface of the dummy gate electrode DG is covered with a silicide layer S3 when the polishing process is completed, an attempt to remove the dummy gate electrode DG formed of silicon by etching as described with reference to FIGS. 18 and 19 is hampered by the silicide layer S3. Namely, the dummy gate electrode DG cannot be removed with the silicide layer S3 formed as a result of polishing. Therefore, even when a metal film forming process (see FIG. 20) and a polishing process (see FIG. 21) are performed to form a metal gate electrode, the metal gate electrode is not formed. Namely, the desired MISFET cannot be formed and the reliability of the semiconductor device declines.

Therefore, to form a metal gate electrode in the case of the above comparison example, it is necessary to perform an additional process to remove the silicide layer S3 formed as a result of the polishing process. Compared with other insulation films or conductive films, the silicide layer is difficult to remove. Removing the silicide layer by wet etching is particularly difficult. Therefore, in the case of the comparison example, it is necessary to remove the silicide layer S3 over the dummy gate electrode DG by dry etching after obtaining the structure shown in FIG. 33 by polishing. This increases the number of processes for semiconductor device manufacture and increases the semiconductor device manufacturing cost.

The reason why, in the comparison example, the silicide layer S3 is formed after the silicide layer S1 (see FIG. 15) is removed by performing a polishing process is that, in the comparison example, a slurry containing an alkaline material (e.g. ammonium) is used in the polishing process performed by a CMP method. When the silicide layer S1 is removed by polishing performed by a CMP method, the nickel contained in the silicide layer S1 separated from the memory gate electrode MG is taken as metal particles into the slurry with a negative oxidation-reduction potential and a pH of 10 to 12.

Subsequently, the heat generated by polishing causes the metal particles and the silicon over the surface of each gate electrode to react with each other to form the silicide layer S3 over the respective gate electrodes including the dummy gate electrode DG. Also, when a chemical solution (e.g. ammonia water) is used in the cleaning process performed after the polishing process, nickel metal particles are possibly left over the semiconductor substrate.

In the present embodiment, unlike in the comparison example, polishing by a CMP method is performed using a slurry containing an acidic aqueous solution (acidic solvent) such as hydrogen peroxide as described with reference to FIGS. 16 and 17. In this way, the slurry has a positive oxidation-reduction potential, so that it is easier for the nickel (Ni) contained in the silicide layer S1 (see FIG. 15) removed by polishing to be present not as metal particles but as Ni²⁺ ions in the slurry. Namely, the nickel cannot easily be present as metal in the slurry. Hence, formation of a silicide layer as a result of reactions, caused by the heat generated by polishing, between nickel present as metal in the slurry and the silicon over the respective gate electrodes can be prevented.

Also, a part of the Ni²⁺ ions become nickel oxide due to an oxidation effect of the acidic aqueous solution contained in the slurry. Since the nickel oxide does not react with the silicon over each gate electrode, formation of a new silicide layer can be prevented.

When conveying the semiconductor substrate from the polishing apparatus to the cleaning apparatus, the semiconductor substrate surface can be kept moist by supplying moistening water with a positive oxidation-reduction potential to the semiconductor substrate. This prevents the nickel ions attached to the surface of each gate electrode from becoming metal to subsequently remain as a silicide layer. This allows the nickel ions to be removed easily in the subsequent cleaning process.

Furthermore, in the comparison example, when nickel metal particles generated in the polishing process are attached to the surface of each gate electrode, it is difficult to remove the metal particles by subsequent cleaning. Compared to such nickel metal particles, the above-mentioned Ni²⁺ ions generated as a result of polishing can be, even when attached to the upper surface of each gate electrode, easily removed using an acidic aqueous solution. Hence, in the present embodiment, after the polishing process described with reference to FIGS. 16 and 17, the first cleaning process is performed using an acidic chemical solution. In this case, the nickel ions are removed together with the silicon layer to which the nickel ions have been attached. Therefore, the nickel ions generated in the polishing process are prevented from becoming metal particles to be then left as a silicide layer which hampers removal of the dummy gate electrode DG.

In the cleaning process performed following the polishing process described with reference to FIGS. 16 and 17, it is conceivable to first perform the second cleaning process in which pure water is used to be followed by the first cleaning process in which an acidic aqueous solution is used. Though, pure water is weakly acidic, it is lower in acidity than the acidic aqueous solution and has a high pH. Therefore, in terms of nickel ion removable performance, the pure water used in the second cleaning process is inferior to the acidic aqueous solution used in the first cleaning process. Therefore, performing the first cleaning process and the second cleaning process in this order is more effective in removing the nickel ions attached to the surface of the semiconductor substrate.

As described above, in the present embodiment, formation of the silicide layer S3 (see FIG. 33) over the upper surface of the dummy gate electrode DG in the polishing process can be prevented, so that, in a subsequent process, the dummy gate electrode DG can be easily removed without being hampered by the silicide layer S3. This allows the dummy gate electrode DG to be appropriately replaced by a metal gate electrode, so that reliability of the semiconductor device is improved. Since it is not necessary to perform an additional process for removing the silicide layer S3 formed over the dummy gate electrode DG, the semiconductor device manufacturing process can be simplified and the semiconductor device manufacturing cost can be reduced.

### Second Embodiment

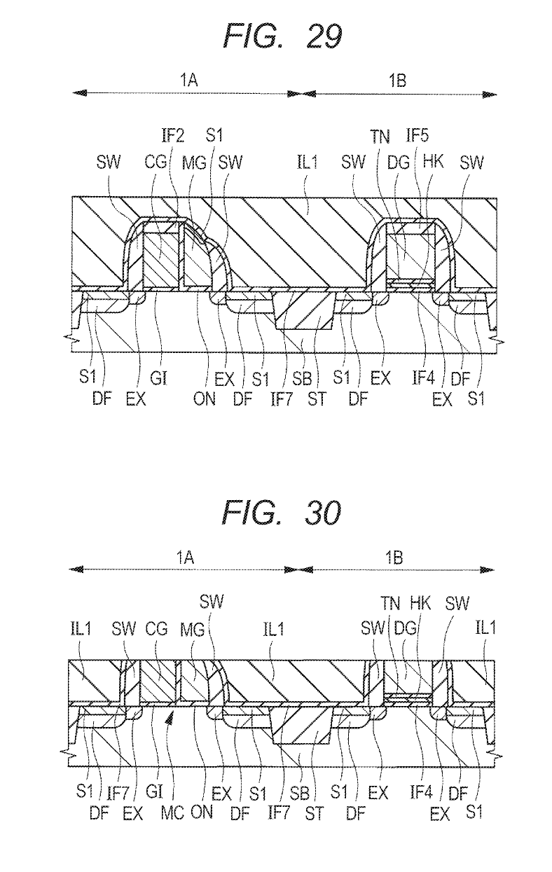

In the following, a semiconductor device manufacturing method according to a second embodiment of the present invention will be described with reference to FIGS. 29 and 30. In the second embodiment, polishing for exposing the dummy gate electrode is progressively performed to achieve higher polishing accuracy. FIGS. 29 and 30 are sectional views of a semiconductor device being manufactured according to the present embodiment.

After the processes described with reference to FIGS. 1 to 15 are performed, a first polishing process is performed to lower the upper surface of the interlayer insulation film IL1 as shown in FIG. 29. This flattens the upper surface of the interlayer insulation film IL1. At this time, none of the insulation film IF7, silicide layer S1, dummy gate electrode DG, control gate electrode CG and memory gate electrode MG is exposed from the interlayer insulation film IL1. Namely, the interlayer insulation film IL1 is polished such that the upper surface of the interlayer insulation film IL1 is upwardly off the silicide layer S1 over the upper surface of the memory gate electrode MG.

Therefore, in the first polishing process, the interlayer insulation film IL1 is polished partway in its depth direction and no other films are polished. Therefore, the silicide layer S1 is not removed and the dummy gate electrode DG is not exposed.

Therefore, the slurry for use in the first polishing process to be performed by a CMP method need not contain an acidic aqueous solution (e.g. hydrogen peroxide solution). For example, an alkaline aqueous solution (e.g. ammonia water) may be used.

Next, as shown in FIG. 30, a polishing process similar to the polishing process (the second polishing process) described with reference to FIGS. 16 and 17 is performed to remove the silicide layer S1 and, thereby, the upper surfaces of the dummy gate electrode DG, control gate electrode CG and memory gate electrode MG are exposed while preventing re-formation of a silicide layer. Subsequently, the processes as described with reference to FIGS. 18 to 27 are performed to complete the semiconductor device of the present embodiment (see FIG. 27).

In the present embodiment, the slurry to be used in the first polishing process described with reference to FIG. 29 need not be acidic. The slurry component is optional. For example, a slurry advantageous in accurately flattening the upper surface of the interlayer insulation film IL1 can be used. This facilitates flattening the upper surface of the interlayer insulation film IL1 (see FIG. 15) having surface irregularities formed at the time of film formation by being affected by the gate electrodes formed over the semiconductor substrate SB.

Therefore, in the second polishing process to be subsequently performed, too, the flatness of the polished upper surface of the interlayer insulation film IL1 can be improved. This enables accurate film formation and polishing in a wiring layer forming process to be performed after elements such as memory cells are formed and, eventually, improves the reliability of the semiconductor device.

### Third Embodiment

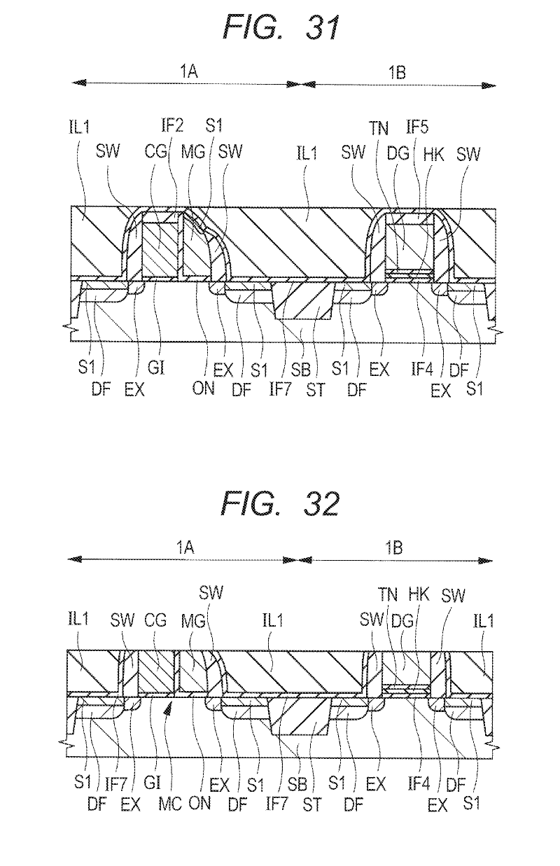

In the following, a semiconductor device manufacturing method according to a third embodiment of the present invention will be described with reference to FIGS. 31 and 32. In the third embodiment, polishing for exposing the dummy gate electrode is progressively performed to achieve higher polishing accuracy. FIGS. 31 and 32 are sectional views of a semiconductor device being manufactured according to the present embodiment.

After the processes described with reference to FIGS. 1 to 15 are performed, a first polishing process is performed to lower the upper surface of the interlayer insulation film IL1 as shown in FIG. 31. This flattens the upper surface of the interlayer insulation film IL1. In this process, the upper surface of the insulation film IF7 is partly exposed, but none of the silicide layer S1, dummy gate electrode DG, control gate electrode CG and memory gate electrode MG is exposed from the interlayer insulation film IL1. Namely, in the first polishing process, the interlayer insulation film IL1 is polished until the insulation film IF7 to function as an etching stopper film is exposed. Neither the silicide layer S1 is removed nor the dummy gate electrode DG is exposed.

Therefore, the slurry for use in the first polishing process to be performed by a CMP method need not contain an acidic aqueous solution (e.g. a hydrogen peroxide solution). For example, an alkaline aqueous solution (e.g. ammonia water) may be used.

Next, as shown in FIG. 32, a polishing process similar to the polishing process (the second polishing process) described with reference to FIGS. 16 and 17 is performed to remove the silicide layer S1 and, thereby, the upper surfaces of the dummy gate electrode DG, control gate electrode CG and memory gate electrode MG are exposed while preventing re-formation of a silicide layer. Subsequently, the processes as described with reference to FIGS. 18 to 27 are performed to complete the semiconductor device of the present embodiment (see FIG. 27).

In the present embodiment, the slurry to be used in the first polishing process described with reference to FIG. 31 need not be acidic. The slurry component is optional. For example, a slurry which makes the interlayer insulation film IL1 formed of a silicide oxide film easy to polish and the insulation film IF7 formed of a silicon nitride film hard to polish can be used. Thus, a slurry with a high selectivity for silicon oxide can be used, so that it is possible to stop polishing in the first polishing process when the insulation film IF7 is exposed. In this way, the amount polished in the subsequent second polishing process can be reduced.

Thus, according to the present embodiment, the uniformity of film thickness, for example, the thickness of the interlayer insulation film IL1 after the second polishing process can be improved to achieve higher polishing accuracy. In this way, thickness variations between polished films can be prevented. This enables accurate film formation and polishing in a later process for forming a wiring layer, etc. and, eventually, the reliability of the semiconductor device is improved.

The invention made by the present inventors has been concretely described based on embodiments, but the invention is not limited to the foregoing embodiments and can be modified in various ways without departing from its scope.

For example, in connection with the foregoing first to third embodiments, processes for forming a memory cell have been described, but, instead of the memory cell, for example, a MISFET with a high withstand voltage may be formed. The MISFET with a high withstand voltage is a field-effect transistor to be driven by a voltage higher than the voltage applied to drive the MISFETQ1 shown in FIG. 27. The MISFET with a high withstand voltage includes a gate electrode formed of the silicon film PS1 over a thick insulation film which has been formed, in the process described with reference to FIG. 11, over the semiconductor substrate SB and which is thicker than the insulation film IF1.

The gate electrode has a larger width than the dummy gate and can be formed in a process similar to the process for forming the control gate electrode. In the process described with reference to FIGS. 18 and 19, the gate electrode is protected by the insulation films IF8 and IF9, so that the gate electrode is not removed. Alternatively, without providing such protection, the gate electrode of the MISFET with a high withstand voltage may be replaced with a metal gate electrode.

Also, in connection with the foregoing first to third embodiments, formation of a high-k film before formation of the dummy gate electrode has been described, but the high-k film may be formed, after formation of the dummy gate electrode, in the groove formed by removing the dummy gate electrode.

What is claimed is:

1. A manufacturing method of a semiconductor device, comprising the steps of:
(a) preparing a semiconductor substrate;
(b) forming a first gate electrode over the semiconductor substrate via a first insulation film in a first area, a dummy gate electrode over the semiconductor substrate via a second insulation film in a second area, first source and drain regions in a main surface of the semiconductor substrate such that the first source and drain regions are respectively on both sides of the first gate electrode, and second source and drain regions in the main surface of the semiconductor substrate such that the second source and drain regions are respectively on both sides of the dummy gate electrode;
(c) forming a first silicide layer on upper surfaces of the first source drain regions and the second source drain regions and a second silicide layer on an upper surface of the dummy gate electrode;
(d) after the step (c), forming a first interlayer insulation film covering the first gate electrode and the dummy gate electrode over the semiconductor substrate;
(e) exposing an upper surface of the first gate electrode and the upper surface of the dummy gate electrode by polishing an upper surface of the first interlayer insulation film and the second silicide layer;
(f) after the step (e), forming a groove over the second insulation film by removing the dummy gate electrode; and
(g) forming a second gate electrode including a metal film in the groove,
wherein a first transistor comprises the first gate electrode and the first source and drain regions and a second transistor comprises the second gate electrode and the second source and drain regions, and
wherein an acidic slurry is used for polishing performed in the step (e).

2. The manufacturing method of a semiconductor device according to claim 1, wherein the acidic slurry contains hydrogen peroxide or hydrochloric acid.

3. The manufacturing method of a semiconductor device according to claim 1, further comprising the steps of:
(e1) after the step (e) and before the step (f), cleaning the semiconductor substrate using a first acidic aqueous solution; and
(e2) after the step (e) and before the step (f), cleaning the semiconductor substrate using pure water.

4. The manufacturing method of a semiconductor device according to claim 3, wherein, after the step (e1), the step (e2) is performed.

5. The manufacturing method of a semiconductor device according to claim 3, wherein the first acidic aqueous solution used in the step (e1) contains oxalic acid or citric acid.

6. The manufacturing method of a semiconductor device according to claim 3, wherein the first acidic aqueous solution used in the step (e1) contains hydrofluoric acid.

7. The manufacturing method of a semiconductor device according to claim 1,
wherein, in the step (b): the first insulation film including a charge accumulation film, the first gate electrode, the second insulation film and the dummy gate electrode are formed; a third gate electrode is formed in the second area over the semiconductor substrate via a third insulation film such that the third gate electrode adjoins a side wall of the first gate electrode via the first insulation film; and, in the main surface of the semiconductor substrate, the first source and drain regions are formed to sandwich the first gate electrode and the second source and drain regions are formed to sandwich the third gate electrode,
wherein, in the step (e), the upper surface of the first gate electrode, an upper surface of the third gate electrode and the upper surface of the dummy gate electrode are exposed by polishing the first interlayer insulation film and the second silicide layer,
wherein a third transistor comprises the third gate electrode and the first source and drain regions, and
wherein a memory cell comprises the first transistor and the third transistor.

8. The manufacturing method of a semiconductor device according to claim 1, further comprising a step (h) of, after the step (g), forming a third silicide layer over an upper surface of the first gate electrode.

9. The manufacturing method of a semiconductor device according to claim 1,
wherein the step (e) includes the steps of:
(e3) flattening the upper surface of the first interlayer insulation film by polishing the first interlayer insulation film such that the upper surface of the first interlayer insulation film is upwardly off the upper surface of the second silicide layer; and
(e4) after the step (e3), exposing the upper surface of the first gate electrode and the upper surface of the dummy gate electrode by polishing the first interlayer insulation film and the second silicide layer,
wherein the acidic slurry is used for polishing in the step (e4).

10. The manufacturing method of a semiconductor device according to claim 9,
wherein, in the step (d), a fourth insulation film to cover the first gate electrode and the dummy gate electrode and the first interlayer insulation film thicker than the fourth insulation film are formed in this order over the semiconductor substrate,
wherein, in the step (e3), the fourth insulation film is exposed by polishing the first interlayer insulation film, and
wherein, in the step (e4), the upper surface of the first gate electrode and the upper surface of the dummy gate electrode are exposed by polishing the fourth insulation film, the first interlayer insulation film and the second silicide layer.

11. The manufacturing method of a semiconductor device according to claim 1, further comprising the steps of:
(i) after the step (g), forming a second interlayer insulation film over the first gate electrode, the second gate electrode and the first interlayer insulation film; and
(j) forming a contact plug through the second interlayer insulation film, the contact plug being electrically coupled to the first transistor and the second transistor.

12. The manufacturing method of a semiconductor device according to claim 1, wherein the first transistor is driven by a voltage higher than a voltage applied to drive the second transistor.

13. The manufacturing method of a semiconductor device according to claim 3, further comprising the step of (e5), after the step (e) and before the steps (e1) and (e2), supplying a second acidic aqueous solution to a surface of the semiconductor substrate when the semiconductor substrate is conveyed.

14. The manufacturing method of a semiconductor device according to claim 1, wherein the second silicide layer contains nickel or cobalt.
